(19) United States
(12) Patent Application Publication
(10) Pub. No.: US 2012/0305070 A1
(43) Pub. Date: Dec. 6, 2012

(54) CYLOMETALATED DYE COMPLEXES AND THEIR USE IN DYE-SENSITIZED SOLAR CELLS

(75) Inventors: Curtis P. Berlinguette, Calgary (CA); Bryan Koivisto, Toronto (CA); Kiyoshi Robson, Calgary (CA)

(73) Assignee: UTI LIMITED PARTNERSHIP, Calgary, AB (CA)

(21) Appl. No.: 13/496,657

(22) PCT Filed: Sep. 16, 2010
(86) PCT No.: PCT/CA10/01430

§ 371 Date: Aug. 23, 2012

Related U.S. Application Data
(60) Provisional application No. 61/243,059, filed on Sep. 16, 2009.

(51) Int. Cl. C07F 15/00; H01L 31/0224; H01L 31/18

(52) U.S. Cl. 136/256; 546/2; 438/98; 257/E31.124

(57) ABSTRACT

The present invention provides a modular approach to preparing a large array of substituted cyclometalated compounds which behave as dyes having intense absorbance bands in the visible spectrum. The compounds include at least one terpyridine-type ligand (tpy) and one cyclometalated tridentate ligand having the bonding motif N,C,N′ or C,N, N′. In particular, compounds of formula (I) and formula (II), as shown, where M and R¹ to R⁴ are as defined herein, are disclosed. The utility of these compounds in dye-sensitized solar cells (DSSCs) is also taught.

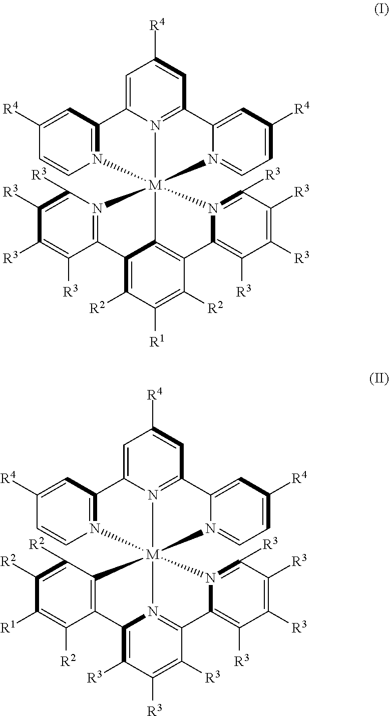

### CROSS REFERENCE TO RELATED U.S. APPLICATIONS

This patent application relates to, and claims the priority benefit of U.S. provisional patent application Ser. No. 61/243,059 filed on Sep. 16, 2009, entitled “CYCLOMETALATED DYE COMPLEXES AND THEIR USE IN DYE-SENSITIZED SOLAR CELLS”, which is incorporated herein by reference in its entirety.

### FIELD OF THE INVENTION

The present invention relates to a complex, a method of manufacturing same and the use of same in a dye-sensitized solar cell.

### BACKGROUND OF THE INVENTION

The dye-sensitized solar cell (“DSSC”) design is a promising, low-cost and more energy-efficient alternative to solid-state, silicon-based solar cell designs.

The DSSC is comprised of two conducting glass electrodes with an electrolyte separating the two. On one electrode is a thin layer of oxide semiconductor material associated with a light-absorbing dye.

DSSC designs employ a metal-based dye complex. A prototypical dye complex comprises a metal ion atom bound by polypyridine ligands [for example, Ru(dcbpy)₂(NCS)₂ (dcbpy=bis(4,4′-dicarboxy-2-,2′-bipyridine)]. Conversion of light energy to electricity is initiated when a photon strikes the metal complex, initiating a metal-to-ligand charge-transfer (MLCT). The ligand must then be capable of transferring or injecting the charge into a semi-conductor whose role is to transfer charge to the anode.

The electrolyte, for example an acetonitrile solution containing iodide/triiodide restores the oxidation state of the metal complex after charge transfer and also receives electrons at the cathode.

The efficiency of conversion of a DSSC is heavily dependent on the properties of the metal-based dye. The ideal dye complex should absorb as much visible light as possible, have redox potentials appropriately matched to the semiconductor and electrolyte for electron-injection and regeneration, respectively, and sustain numerous redox turnovers under light irradiation.

The monodentate electron-donating thiocyanate (NCS) electron-donating ligand is believed to be possibly less chemically stable than the other components of the dye complex. Substituting the NCS ligand, however, may compromise the energy-conversion efficiency of the dye complex and inhibit its ability to act as a sensitizer within a DSSC system. Thus one focus of DSSC research is the elucidation of stable, efficient dye complexes.

Tris-bidentate [Ru(bpy)₃]²⁺-type (bpy=2,2′-bipyridine) complexes have been shown to exhibit better photophysical properties than bis-tridentate [Ru(tpy)₂]²⁺-type (tpy=2,2′:6,2′-terpyridine) complexes [Juris et al. 1988; Sauvage et al. 2006; Medlycott 2005]. The latter compounds, however, may be less-easily incorporated into larger assemblies owing to the formation of enantiomers or diastereomers [Keene 1997].

Some research efforts have focussed on the development of NCS-free metal-based dye complexes with the ability to absorb a greater fraction of the solar spectrum, particularly longer wavelengths, thereby improving the efficiency of DSSC systems. One such approach is to lower the lowest-unoccupied molecular orbital (LUMO) derived primarily of the π* system of the polypyridyl ligand [Grätzel 2005].

Another approach to shifting the absorption profile closer to the near-infrared region of the electromagnetic spectrum is to substitute the Ru—N dative bond with a Ru—C σ bond [Bomben et al. 2009].

Moreover, stabilization of the low-lying excited states can be enhanced by incorporation of electron-withdrawing substituents on the tpy ligands of Ru complexes [Maestri et al. 1995].

International patent application publication no. WO/0210286 to Alebbi et al. teaches cyclometalated dye complexes incorporating mono- and bidentate ligands.

European application publication no. EP 2036955 to Yoneda et al. teaches the synthesis of bis-tridentate and tris-bidentate cyclometalated dye complexes featuring substituted Ru—C σ bonds and electron-withdrawing moieties.

Nazeeruddin et al. (2001) discloses a series of Ru(II) sensitizers derived from carboxylated terpyridyl complexes of tris-thiocyanato Ru(II) complexes.

Bessho et al. (2009) discloses bidentate polypyridine cyclometalated dye complexes featuring substituted Ru—C σ bonds and electron-withdrawing moieties.

Wadman et al. (2009) discloses tridentate polypyridine cyclometalated dye complexes featuring substituted Ru—C σ bonds and electron-withdrawing moieties.

Maestri et al. (1995) discloses polypyridine cyclometalated dye complexes that incorporate electron-donating and electron-withdrawing moieties to increase the molar extinction coefficient.

### SUMMARY OF THE INVENTION

In an embodiment of the invention there is provided a complex of formula (I)

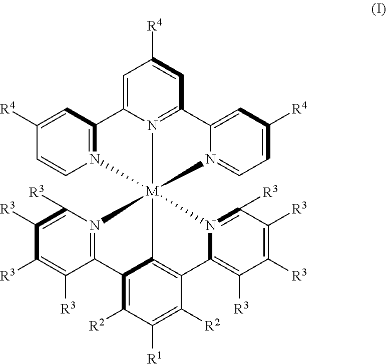

wherein M is an element belonging to Group 6, Group 8, Group 9, Group 10 or Group 11 of the long-form Periodic Table, R¹ is an electron-donating or -withdrawing substituent or H, R² are each independently an electron-donating substituent or H, R³ are each independently an electron-donating substituent, an electron-withdrawing substituent or H, and R⁴ are each independently an electron-withdrawing or electron-donating substituent or H.

In another embodiment of the invention there is provided a complex of the formula (II)

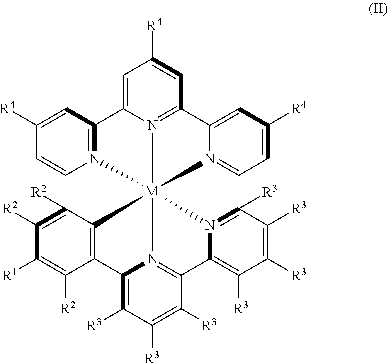

wherein M is an element belonging to Group 6, Group 8, Group 9, Group 10, or Group 11 of the long-form Periodic Table, R¹ is an electron-donating substituent or an electron-withdrawing substituent or H, R² are each independently an electron-donating or -withdrawing substituent or H, R³ are each independently an electron-donating substituent, an electron-withdrawing substituent or H, and R⁴ are each independently an electron-withdrawing or -donating substituent or H.

In another embodiment of the invention there is provided a complex of the formula (III)

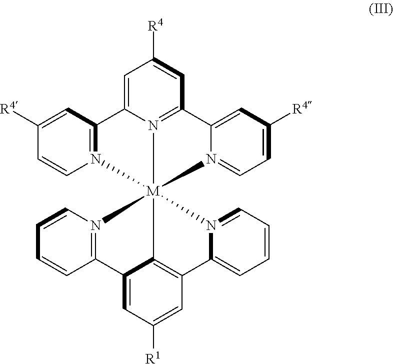

wherein M is an element belonging to Group 6, Group 8, Group 9, Group 10, or Group 11 of the long-form Periodic Table, R¹ is an alkoxy group, an amine, an alkyl or a substituted five-membered heterocycle, R⁴ is a halogen, an anchoring group, NO₂, or an electron-deficient aromatic, and R⁴′ and R⁴″ are each independently a halogen, an anchoring group, NO₂, an electron-deficient aromatic or H.

In another embodiment of the invention there is provided a complex of the formula (IV)

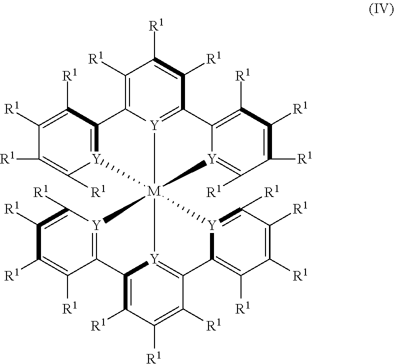

wherein M is an element belonging to Group 6, Group 8, Group 9, Group 10, or Group 11 of the long-form Periodic Table, R¹ is an electron-donating substituent or an electron-withdrawing substituent or H; and Y=C or N, where exactly two (2) Y atoms are C and four (4) Y atoms are N.

In another embodiment of the invention there is provided a solar cell comprising an anode, a cathode and an electrolyte in electrical communication with each of the anode and the cathode wherein the anode comprises a compound according to the invention.

In another embodiment of the invention there is provided an anode for use in a solar cell formed by contacting a substrate with a solution comprising a compound according to the invention thereby causing the compound to be associated with the semiconductor.

In another embodiment of the invention there is provided a method for the manufacture of a solar cell comprising contacting an anode comprising a substrate with a solution comprising a compound according to the invention, thereby causing the compound to be associated with the semiconductor.

Other and further advantages and features of the invention will be apparent to those skilled in the art from the following detailed description of an embodiment thereof, taken in conjunction with the accompanying drawings.

### BRIEF DESCRIPTION OF THE DRAWINGS

Preferred embodiments of the invention will now be described, by way of example only, with reference to the drawings, in which:

FIG. 1 is a schematic of a synthesis of the [Ru(tpy-R¹)(tpy-R²)](PF₆)₂ (Compounds 1-6) and [Ru(tpy-R²)(dpb-R¹)]PF₆ (Compounds 7-10) series from Example 1. (Reaction conditions: a) RuCl₃, MeOH_{(aq)} EtOH, Δ, 12 h; b) N-ethylmorpholine, Δ, 12 h; c) KMnO₄, H₂O, RT, 16 h; d) NH₄PF₆.)

FIG. 2 is a schematic depicting the labelling scheme for assignment of ¹H NMR signals from Example 1.

FIG. 3 is a graph depicting ¹H NMR spectra of Example 1 compounds [Ru(tpy-2-furyl)(tpy-OMe)]²⁺ (Compound 5), [Ru(tpy-2-furyl)(dpb-OMe)]⁺ (Compound 10), and [Ru(tpy-2-furyl)(dpb)]⁺ (Compound 9) in CD₃CN solutions at ambient temperature. Signals are assigned according to the labelling scheme provided in FIG. 2.

FIG. 4 is a graph depicting UV-vis spectra of Example 1 Compounds 1-6 in MeCN at ambient temperature.

FIG. 5 depicts cyclic voltammograms of Example 1 Compounds [Ru(tpy-2-furyl)(tpy-OMe)](PF₆)₂ (Compound 5); [Ru(tpy-2-furyl)(dpb-OMe)]PF₆ (Compound 10); and [Ru(tpy-2-furyl)(dpb)]PF₆ (Compound 9) in MeCN at ambient temperature (scan rate=100 mV/s). Reversible redox potentials (vs NHE) are listed in Tables 1 and 2.

FIG. 6 is a graph depicting UV-vis spectra for Example 1 Compounds [Ru(tpy-2-furyl)(tpy-OMe)](PF₆)₂ (Compound 5); [Ru(tpy-2-furyl)(dpb-OMe)]PF₆ (Compound 10); and [Ru(tpy-2-furyl)(dpb)]PF₆ (Compound 9) in MeCN at ambient temperature. Assignments for λₙ are provided in FIG. 7.

FIG. 7 depicts an energy level diagram generated from the TD-DFT calculations for Example 1 Compounds 5 and 10. Prominent electronic transitions (λₙ) and select molecular orbitals are shown (see FIG. 6 for correlation of the λₙ transitions to the experimental spectra).

FIG. 8 depicts the electronic absorbance spectra for the (a and b) [Ru(bpy)₂(L)]^{z}, (c) [Ru(tpy)(L)]^{z} and (d) [Ru(tpy)(L)(Cl)]^{z} series recorded in MeCN at ambient temperature from Example 2.

FIG. 9 is a summary of TD-DFT results for Example 2 [Ru(bpy)₂(ĈN)]^{z} series.

FIG. 10 is a summary of TD-DFT results for Example 2 [Ru(tpy)(L)]^{z} series.

FIG. 11 is a summary of TD-DFT results for Example 2 [Ru(tpy)(L)(Cl)]^{z} series.

FIG. 12 depicts ¹H NMR spectra of Example 2 Compounds 11, 15, 13, and 18 in CD₃CN solutions at ambient temperature.

FIG. 13 depicts cyclic voltammograms of bidentate Example 2 Compounds [Ru(bpy)₃](PF₆)₂ (11) and [Ru(bpy)₂(ppy)]PF₆ (15), and tridentate complexes [Ru(tpy)₂](PF₆)₂ (13) and [Ru(tpy)(pbpy)]PF₆ (18) in acetonitrile at 298 K (scan rate=100 mV/s).^{16,21} Peak potentials (vs NHE) for the redox couples are indicated in Table 3.

FIG. 14 is a schematic depicting a dye-sensitized solar cell design.

### DETAILED DESCRIPTION OF THE INVENTION

Generally speaking, the systems described herein are directed to cyclometalated dye complexes, methods of producing them, and their use in dye-sensitized solar cells. As required, embodiments of the present invention are disclosed herein. However, the disclosed embodiments are merely exemplary, and it should be understood that the invention may be embodied in many various and alternative forms. The figures are not to scale and some features may be exaggerated or minimized to show details of particular elements while related elements may have been eliminated to prevent obscuring novel aspects.

Therefore, specific structural and functional details disclosed herein are not to be interpreted as limiting but merely as a basis for the claims and as a representative basis for teaching one skilled in the art to variously employ the present invention. For purposes of teaching and not limitation, the illustrated embodiments are directed to cyclometalated dye complexes, methods of producing them, and their use in dye-sensitized solar cells.

As used herein, the term “about” or “approximately”, when used in conjunction with ranges of dimensions, temperatures or other chemical or physical properties or characteristics is meant to cover slight variations that may exist in the upper and lower limits of the ranges of any property including dimensions, concentrations and any other physical or chemical property or parameter so as to not exclude embodiments where on average most of the properties/parameters are satisfied but where statistically dimensions may exist outside this region.

As used herein, the coordinating conjunction “and/or” is meant to be a selection between a logical disjunction and a logical conjunction of the adjacent words, phrases, or clauses. Specifically, the phrase “X and/or Y” is meant to be interpreted as “one or both of X and Y” wherein X and Y are any word, phrase, or clause.

“Electron-withdrawing substituents” (also referred to as Electron-withdrawing groups (EWG)) is used herein to describe substituents on an aromatic ring that have a negative Hammett substituent value as described by Leffler et al., Rates and Equilibria of Organic Reactions, J. Wiley and Sons Inc., p. 172, New York (1963).

“Electron-donating substituents” (also referred to as Electron-donating groups (EDG)) is used herein to describe substituents on an aromatic ring that have a positive Hammet substituent value as described by Leffler et al., Rates and Equilibria of Organic Reactions, J. Wiley and Sons Inc., p. 172, New York (1963).

“Molecular extinction coefficient” is used herein to describe the amount of light absorbed by one mole of a molecule of a given pathlength.

“Alkoxy” is used herein to describe a straight chain or branched oxy-containing anion suitably each having alkyl portions of 1 to about 20 carbon atoms. Examples of alkoxy include methoxy, ethoxy, propoxy, butoxy and tert-butoxy.

“Alkyl” is used herein to describe straight chain, branched chain or cyclic hydrocarbon groups having from 1 to 12 carbon atoms, suitably 1 to 6 carbon atoms, more suitably 1 to 4 carbon atoms. Suitable alkyls include methyl, ethyl, propyl, isopropyl, butyl, isobutyl, sec-butyl, tert-butyl, pentyl, neopentyl, hexyl, cyclopropyl, cyclobutyl, cyclopentyl or cyclohexyl.

“Amine” is used herein to describe a nitrogen containing a lone pair of electrons with one or more alkyl or aryl substituents. For the present invention, suitable alkyl substituents include methyl, ethyl, propyl, isopropyl, butyl, isobutyl, sec-butyl, tert-butyl, pentyl, neopentyl, hexyl, cyclopropyl, cyclobutyl, cyclopentyl or cyclohexyl. Aryl is used herein to describe six membered aromatic carbon rings. Suitable aryls include phenyl, tolyl, xylyl, mesityl, anisole or aniline.

“Anchoring group” is used herein to describe groups with a structural motif such it is capable of providing intimate electronic communication between the metal of the compound of the present invention and the semiconductor. Suitable anchoring groups have been previously disclosed [Galoppini 2004] and would be known to persons skilled in the art. Suitable anchoring groups include —CO₂H and —PO₃H₂.

“Five-membered aromatic heterocycle” is used herein to describe monocyclic, aromatic, heterocyclic groups containing at least one heteroatom ring atom selected from nitrogen, sulphur and oxygen and containing up to 5 ring atoms and up to 4 carbon ring atoms. Suitable five-membered aromatic heterocycles include pyrroles, furyls, thiophenes and phospholes.

“Electron-deficient aromatic” is used herein to describe any aromatic ring that has less electron density than benzene. Suitable electron-deficient aromatics include pyridine, pyrimidine, halogenated aryl rings or an electron-withdrawing substituted phenyl ring.

“Electron-withdrawing substituted phenyl ring” is used herein to describe a six membered aromatic carbon ring, with low electron density due to periphery substitution of electron-withdrawing substituents. Suitable electron-withdrawing substituted phenyl rings include C₆H₄CF₃ or C₆H₄CN.

“Halogen” is used herein to describe any one of fluorine, chlorine, bromine, iodine and astatine.

Cyclometalated dye complexes disclosed previously lack robust dipole effects distributed across their structures and may be limited in their ability to efficiently serve as sensitizers within a DSSC.

The present invention provides cyclometalated dye complexes comprising bis-tridentate ligands of the [M(tpy)(dpb)]¹⁺ and/or [M(tpy)(pbpy)]¹⁺ motif where M is an element belonging to Group 6, Group 8, Group 9, Group 10, or Group 11 of the long-form Periodic Table. Substitution of a Ru—C σ bond for a Ru—N dative bond provides for greater charge delocalization as compared to the [Ru(tpy)₂]²⁺ motif.

In an embodiment of the invention there is provided a complex of formula (I)

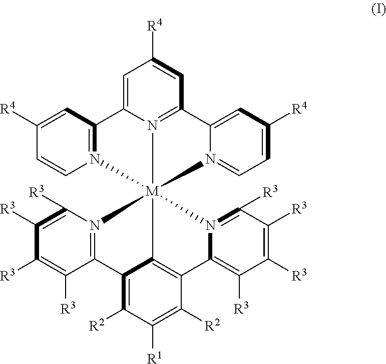

wherein M is an element belonging to Group 6, Group 8, Group 9, Group 10, or Group 11 of the long-form Periodic Table, R¹ is an electron-donating or -withdrawing substituent or H, R² are each independently an electron-donating substituent or H, R³ are each independently an electron-donating substituent, an electron-withdrawing substituent or H, and R⁴ are each independently an electron-withdrawing or electron-donating substituent or H.

In another embodiment of the invention there is provided a complex of the formula (II)

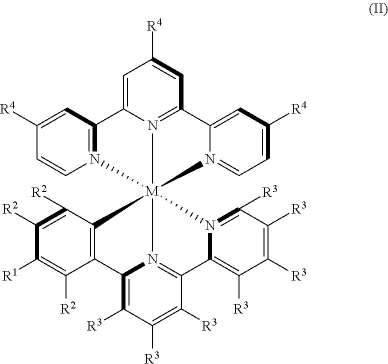

wherein M is an element belonging to Group 6, Group 8, Group 9, Group 10, or Group 11 of the long-form Periodic Table, R¹ is an electron-donating substituent or an electron-withdrawing substituent or H, R² are each independently an electron-donating or -withdrawing substituent or H, R³ are each independently an electron-donating substituent, an electron-withdrawing substituent or H, and R⁴ are each independently an electron-withdrawing or -donating substituent or H.

In a preferred embodiment of the complex of formula (II) R¹ is an electron-withdrawing substituent or H, R² are each independently an electron-withdrawing substituent, electron-donating substituent or H, R³ are each independently an electron-withdrawing substituent, and R⁴ are each independently an electron-donating substituent.

In yet another preferred embodiment of the complex of formula (II) R¹ is an electron-withdrawing substituent or H, R² are each independently an electron-withdrawing substituent, electron-donating substituent or H, R³ are each independently an electron-donating substituent, and R⁴ are each independently an electron-withdrawing substituent.

This scenario is one possible optimal configuration because the position of the electron-withdrawing groups, R¹ and R², increase the oxidation potential of the dye complex to enhance the rate of regeneration of the photooxidized dye in the device. The position of the electron-withdrawing groups, R³, relative to the phenyl ring accommodates rapid electron-injection into the anode material.

The position of the electron-withdrawing groups in this scenario also serves to increase the oxidation potential of the dye. The position of the electron-withdrawing groups, R⁴, relative to the phenyl ring accommodates rapid electron-injection into the anode material.”

In another embodiment of the invention there is provided a complex of the formula (III)

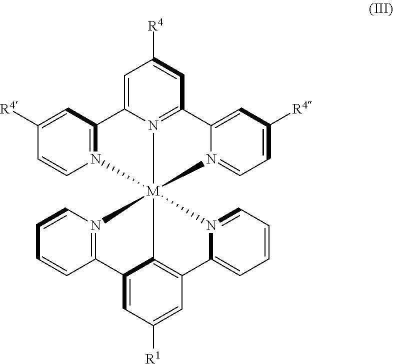

wherein M is an element belonging to Group 6, Group 8, Group 9, Group 10, or Group 11 of the long-form Periodic Table, R¹ is an alkoxy group, an amine, an alkyl or a substituted five-membered heterocycle, R⁴ is a halogen, an anchoring group, NO₂, or an electron-deficient aromatic, and R⁴′ and R⁴″ are each independently a halogen, an anchoring group, NO₂, an electron-deficient aromatic or H.

In another embodiment of the invention there is provided a complex of the formula (IV)

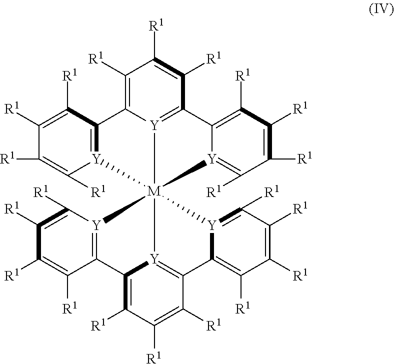

wherein M is an element belonging to Group 6, Group 8, Group 9, Group 10, or Group 11 of the long-form Periodic Table, R¹ is an electron-donating substituent or an electron-withdrawing substituent or H; and Y=C or N, where exactly two (2) Y atoms are C and four (4) Y atoms are N.

In another embodiment of the invention there is provided a solar cell comprising an anode, a cathode and an electrolyte in electrical communication with each of the anode and the cathode wherein the anode comprises a compound according to the invention.

In another embodiment of the invention there is provided an anode for use in a solar cell formed by contacting a substrate with a solution comprising a compound according to the invention thereby causing the compound to be associated with the semiconductor.

In another embodiment of the invention there is provided a method for the manufacture of a solar cell comprising contacting an anode comprising a substrate with a solution comprising a compound according to the invention, thereby causing the compound to be associated with the semiconductor.

While not intending to be limited to a specific theory of the invention, certain advantageous features of the complex arise from the formation of a dipole moment within the dye compound and increased delocalization of the HOMO thereby increasing the molar extinction coefficient of the dye complex.

Addition of an electron-donating substituent at the cyclometalating ring of the dpb ligand allows for further delocalization of the HOMO thereby increasing the molar extinction coefficient of the dye complex thereby increasing the ability of the dye complex to absorb light.

The dye complex of the present invention may be synthesized using any element belonging to Group 6, Group 8, Group 9, Group 10, or Group 11 of the long-form Periodic Table. Preferred elements are Iron, Ruthenium (Ru), Osmium, Iridium, Cobalt, Palladium, Platinum and Chromium. In a preferred embodiment, the element is Ru.

The dye complex of the present invention further incorporates electron-donating substituents at the para position of the benzene ring of the dpb ligand.

Further, the dye compounds of the present invention incorporate electron-withdrawing substituents at the 4′ position of the pyridine rings of the tpy ligand. In an embodiment of the invention, an electron-withdrawing substituent is at the 4′ position of the central pyridine ring of the tpy ligand. In another embodiment, electron-withdrawing substituents are positioned at the 4′ position of all three pyridine rings of the tpy ligand.

The positioning of electron-donating and electron-withdrawing substituents within the dye compound creates an enhanced dipole moment thereby increasing electron delocalization across more carbon atoms within the molecule. Increased electron delocalization allows for greater light absorbance.

Additionally, delocalization of the HOMO over both the phenyl ring and the metal facilitates enhanced electronic communications between the electron-donating substituent and the dye complex centre.

The positioning of an electron-donating group at the benzene ring of the dpb ligand further enhances the efficiency with which excited electrons are injected into the semi-conductor oxide by inducing an electronic/molecular dipole.

The presence of electron-withdrawing substituents on the tpy ligand serves to stabilize the LUMO, thus red-shifting the absorption profile. In a preferred embodiment, electron-withdrawing substituents are located at the 4′ position of both pyridine ring members of the dpb ligand.

Alternatively, the dipole moment of the dye complex may be enhanced by the addition of electron-donating substituents at the pyridine ring members of the dpb ligand. In one embodiment, electron-donating substituents are located at the 4′ position of both pyridine ring members of the dpb ligand.

Suitable electron-donating substituents include alkoxy groups, amines and substituted five-membered heterocycles.

Suitable electron-withdrawing substituents include halogens, anchoring groups, NO₂, or electron-deficient aromatics.

In one embodiment of the invention, an electron-withdrawing carboxyl (CO₂H) group is located at the 4′ position of the central pyridine ring of the tpy ligand and an electron-donating methoxy (—OMe) group is located at the para position of the benzene ring of the dpb ligand.

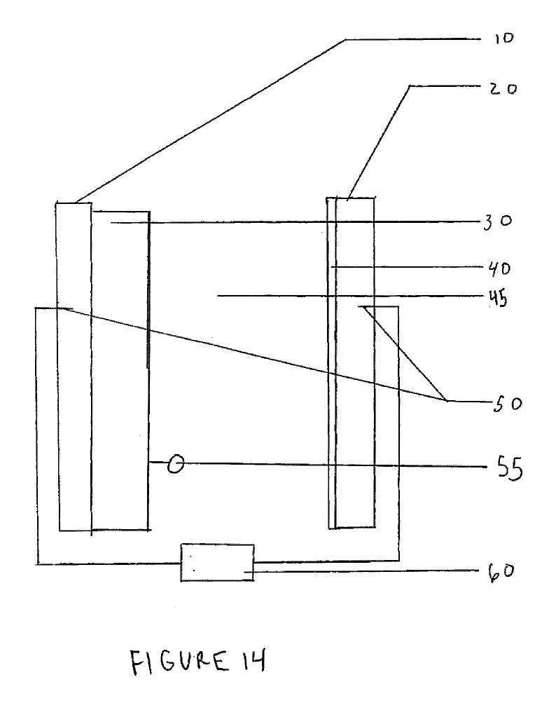

A DSSC is shown in FIG. 14. Construction of a DSSC has been previously described [Ito et al. 2007] and would be well understood by a person skilled in the art. Briefly, the DSSC comprises and anode (10) and a cathode (20) arranged in a sandwich-like configuration. Separating the two electrodes is an electrolyte (45) and a polymer spacer (not shown) which acts to isolate the two conductive electrodes and seal in the electrolyte. Electrical connections (50) are provided on the anode (10) and the cathode (20). An example of a material from which the electrodes may be constructed is fluorine-doped tin oxide conductive glass though other materials are known to persons skilled in the art. The purpose of the electrolyte (45) is to restore the oxidation state of the light-absorbing dye and to receive electrons at the cathode (20). An example of an electrolyte is an acetonitrile solution containing iodide and triiodide, though a person skilled in the art would be aware of other electrolytic compounds that could also serve this purpose.

At the anode (10) is deposited a thin layer of semiconductor material (30). An example of a semiconductor material is titanium oxide (TiO₂) though other semiconductors may be known to a person skilled in the art. An example of the thickness of the layer of semiconductor material is about 12 μm though other thicknesses may be known to a person skilled in the art.

A person skilled in the art would be aware of several methods by which semiconductor material may be deposited at the anode (10). An example of a method by which semiconductor material may be deposited at the anode (10) is to screen print a layer of semiconductor paste on the anode followed by sintering at elevated temperatures. After the semiconductor (30) has been deposited at the anode (10), the anode (10) may be subject to an appropriate heat treatment and further post treatments as would be understood by a person skilled in the art.

A light-absorbing dye (55) is associated with the semiconductor anode (10). One means of associating the dye (55) with the anode (10) is to immerse the heat-treated anode (10) in a dye solution for several hours such that the porous semiconductor material adsorbs the dye. An example of a concentration of dye solution suitable for adsorption is 2×10⁻⁴M though a person skilled in the art would be aware of other suitable concentrations. The association of the light-absorbing dye and the semiconductor is maintained through the chemical bond achieved through a condensation reaction between the anchoring group of the dye complex and the semiconductor material.

Adsorption is one method by which the light-absorbing dye (55) may be integrated, incorporated or otherwise associated with the semiconductor anode (10). Other methods for achieving association of the light-absorbing dye and the semiconductor anode would be known to a skilled reader.

Construction of the cathode (20) is well understood by a person skilled in the art. An example of a method by which a cathode may be constructed is to drill a small hole in the non conductive side of the cathode. A small amount of platinum (for example 5-10 μg/cm²) is deposited on the cathode to catalyze the reduction of the electrolyte. One method of depositing platinum is to screen print a thin layer of platinum paste (40) on the cathode (20). An example of the thickness of the layer of platinum paste is about 1 nm though other thickness may be known to a person skilled in the art. The cathode is then sintered at elevated temperatures, and cooled back to room temperature.

Methods of cell assembly are well known to persons skilled in the art. An example of a method by which the solar cell may be assembled is to place a thin gasket material around the dye coated semiconductor material. An example of gasket material is surlyn though other suitable materials would be known to a person skilled in the art. An example of the thickness of the gasket material is about 15 to about 100 μm though other thicknesses would be known to a person skilled in the art. The cathode (20) is placed at the top of the area surrounded by the gasket. A current is passed through the cathode (20) to cause resistive heating thereby melting the gasket material and sealing the cell when pressure is applied.

An example of a method by which the solar cell may be filled with electrolyte is to place the cell in a vacuum desiccator with a drop of electrolyte over the hole in the cathode. Vacuum is applied until escaping gases from the cell interior has stopped. The vacuum is released slowly and the electrolyte is drawn into the space between the anode and cathode. The hole in the cathode is sealed either with a strip of bynel and a microscope slide or an aluminum-backed strip of bynel. Other methods of filling the solar cell with electrolyte would be known to a person skilled in the art.

Current collection of the anode (10) and cathode (20) may be enhanced by application of busbars (not shown).

Other means of constructing a DSSC would be well understood by a person skilled in the art.

Operation of a DSSC is well understood by a person skilled in the art and can be understood with reference to FIG. 14. The DSSC relies on electron-transfer from a photo-excited dye to a thin mesoporous semi-conductor on an electrode. The dye molecule (55) is subsequently reduced by the electrolyte (45), which, in turn, is regenerated at the cathode (20) by electrons that migrate through an external load (60).

The advantages of the present invention are further illustrated by the following examples. The examples and their particular details set forth herein are presented for illustration only and should not be construed as a limitation on the claims of the present invention.

### Example 1

### Preparation of Compounds

The following examples describe the synthesis and testing of embodiments of cyclometalated Ru(II) dye compounds (Compounds 1-10) of Example 1. These embodiments should not be construed as limiting the present invention. The preparation of other cyclometalated Ru (II) dye compounds is within the purview of a person skilled in the art.

Compounds 1-10 are as follows:

| | | |
|---|---|---|
| 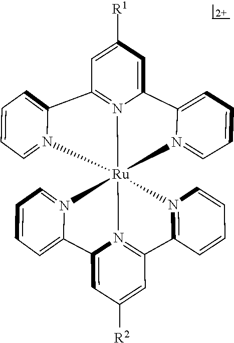 | R¹ = R² = H R¹ = H, R² = CO₂H R¹ = OMe, R² = CO₂H R¹ = H, R² = 2-furyl R¹ = OMe, R² = 2-furyl R¹ = R² = 2-furyl | 1 2 3 4 5 6 |
| 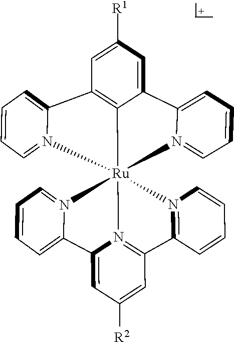 | R¹ = R² = H R¹ = OMe, R² = H R¹ = H, R² = 2-furyl R¹ = OMe, R² = 2-furyl | 7 8 9 10 |

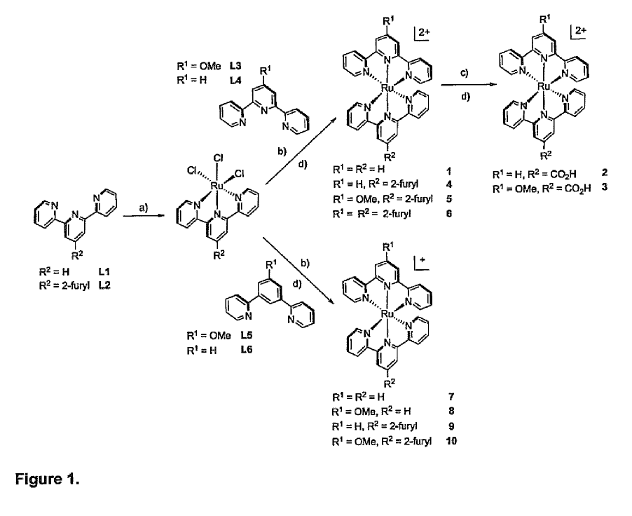

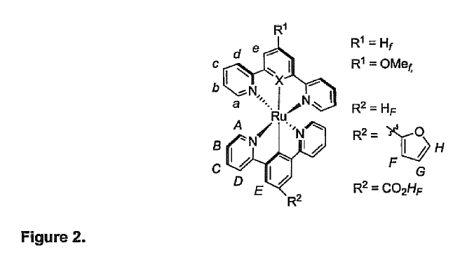

A typical procedure for the synthesis of heteroleptic terpyridyl and cyclometalated Ru compounds is presented in FIG. 1. Preparation of these heteroleptic compounds involves the initial coordination of a polypyridyl ligand to the Ru center (FIG. 2a), followed by the addition of the respective polypyridyl or cyclometalating ligand (FIG. 2b). Owing to the electronic demands of cyclometalation, polypyridyl ligands were ligated first, followed by cyclometalation in the presence of a reductant (N-ethylmorpholine). Anion exchange reactions were carried out for all cationic compounds so that microcrystalline samples could be isolated; all analyses were carried out on the PF₆⁻ salts of the cationic Compounds 1-10. Typical yields of the heteroleptic cyclometalated compounds are lower than those achieved with the analogous pyridyl-based reactions; this is likely a result of the additional purification steps (i.e., chromatography) required to separate the product from the common homoleptic byproducts (i.e. Ru(tpy-R)₂]²⁺). Furthermore, because of their electron-rich nature, some cyclometalated compounds require the addition of ascorbic acid to the eluent to prevent premature oxidation during the chromatography procedures.

All reactions and manipulations were performed using solvents passed through an MBraun™ solvent purification system prior to use; chloroform (CHCl₃) and tetrahydrofuran (THF) solvents were analytical grade (without stabilizer). Unless stated otherwise, all reagents were purchased from Aldrich and used without further purification; RuCl₃.3H₂O was purchased from Pressure Chemical Company. Purification by column chromatography was carried out using silica (Silicycle™: Ultrapure Flash Silica™) or basic alumina (Fluka™). Analytical thin-layer chromatography (TLC) was performed on aluminium-backed sheets pre-coated with silica 60 F254 adsorbent (0.25 mm thick; Merck, Germany) or with plastic-backed sheets pre-coated with basic alumina 200 F254 adsorbent (0.25 mm thick, Selecto Scientific: Georgia, USA) and visualized under UV light. Routine ¹H and ¹³C NMR spectra were recorded at 400 MHz and 100 MHz, respectively, on a Bruker™ AV 400 instrument at ambient temperature unless otherwise stated. Chemical shifts (δ) are reported in parts per million (ppm) from low to high field and referenced to residual non deuterated solvent. Standard abbreviations indicating multiplicity are used as follows: d=doublet; m=multiplet; s=singlet; t=triplet. All proton assignments correspond to the generic molecular scheme depicted in FIG. 2. Elemental analysis, electrospray ionization (ESI), and high-resolution electron impact (EI) mass spectrometry (MS) data were collected at the University of Calgary. Ligands were prepared according to published procedures (with additional purification steps by column chromatography where necessary) as follows: L2 (4′-(furan-2-yl)-2,2′:6′,2″-terpyridine) [Constable et al. 2007; Husson et al. 2003], L3 (4′-methoxy-2,2′:6′,2″-terpyridine) [Chambers et al. 2006] and L5 (1,3-di(pyridin-2-yl)benzene) [Soro et al. 2005], and compounds RuCl₃(L1) [Sullivan et al. 1980].

Compounds 4-10 were prepared using the following steps: A flask containing 0.40 mmol of RuCl₃(L1 or L2) and 0.40 mmol of L1, L2, L3, L4 or L5 in 30 mL of a MeOH:H₂O (5:1 v/v) mixed solvent system and 5 drops of N-ethylmorpholine was stirred at reflux under N₂ for 10 h. The solvent was then removed in vacuo and the crude mixture was preabsorbed onto either silica or basic alumina (conditions provided below).

The synthesis of Compounds 1 [Maestri et al. 2009], 6 [Constable et al. 2007] and 7 [Wadman et al. 2009] have been disclosed previously.

### (1) Preparation of [RuCl₃(tpy-2-furyl)] and RuCl₃(L2)

A solution of tpy-2-furyl (286 mg, 0.956 mmol) and RuCl₃.3H₂O (250 mg, 0.956 mmol) in absolute EtOH (750 mL) was heated at reflux for 3 h. The solid was isolated by filtration and washed with EtOH (2×20 mL) and diethyl ether, and then left to dry in air to yield 400 mg of a red/brown solid product (yield=82.6%). Anal. Calcd for C₁₉H₁₃Cl₃N₃ORu: C, 45.03; H, 2.59; N, 8.29. Found: C, 44.94; H, 2.78; N, 8.14.

### (2) Preparation of 2,2′-(5-methoxy-1,3-phenylene)dipyridine (Hdpb-OMe; L4)

A THF (150 mL) solution containing 1,3-dibromo-5-methoxybenzene (1.10 g, 4.10 mmol) and Pd(PPh₃)₄ (0.48 g, 0.41 mmol) was charged with a 0.5 M THF solution of 2-pyridylzinc bromide (21 mL, 10 mmol). The solution was stirred at reflux for 14 h, cooled and then quenched with a saturated aqueous NaHCO₃ solution (100 mL) and washed with aqueous EDTA. The crude product was extracted with diethyl ether (2×100 mL), and the organic fractions were collected and dried over MgSO₄. The solvent was removed in vacuo to afford an oil that was purified by column chromatography [Al₂O₃:Et₂O, Rt=0.60]; the resultant oily product converted to a white solid upon standing (850 mg; yield=78%). ¹H NMR (300 MHz, CDCl₃): δ=8.70 (d, 2H, ³J=7 Hz, Hₐ), 8.20 (s, 1H, H_{f}), 7.77 (d, 2H, ³J=8 Hz, H_{b}), 7.75 (t, 2H, ³J=8 Hz, H_{c}) 7.66 (s, 2H, Hₑ), 7.25 (t, 2H, ³J=8 Hz, H_{b}), 3.97 (s, 3H, H_{g}); ¹³C NMR (100 MHz, CDCl₃): δ=160.7, 157.2, 149.7, 141.4, 136.9, 122.5, 121.0, 118.2, 113.3, 55.8; HRMS (EI): m/z=262.1101 [(M)⁺] (Calcd for C₁₇H₁₄N₂O⁺: m/z=262.1106).

### (3) Preparation of [Ru(tpy-CO₂H)](PF₆)₂ (Compound 2)

Solid KMnO₄ (1.94 g, 30 eq) was added to [Ru(py)(tpy-2-furyl)](NO₃)₂ (310 mg, 0.41 mmol) in 30 mL of H₂O and then stirred at room temperature overnight. After the mixture was filtered to remove MnO₂, solvent was removed and the solid was then preabsorbed on silica. The target complex was isolated as the orange band from column chromatography [SiO₂:(acetone:MeOH:sat. aq. KNO₃)(6:3:1)]. The resultant solid was reconstituted in water, acidified using acetic acid and the product precipitated as the PF₆⁻ salt using saturated aqueous NH₄PF₆ to yield 230 mg of a red solid product (yield=62%). ¹H NMR (400 MHz, CD₃CN): δ=9.34 (s, 2H, H_{E}), 8.77 (d, 2H, ³J=8 Hz, Hₑ), 8.68 (d, 2H, ³J=8 Hz, H_{A}), 8.50 (d, 2H, ³J=8 Hz, Hₐ), 8.43 (t, 1H, ³J=8 Hz, H_{f}), 7.93 (ddd, 4H, ³J=8 Hz, 7 Hz, ⁴J=1 Hz, H_{B}, H_{b}), 7.40 (d, 2H, ³J=7 Hz, H_{D}), 7.36 (d, 2H, ³J=7 Hz, H_{d}), 7.18 (ddd, 2H, ³J=8 Hz, 7 Hz, ⁴J=1 Hz, H_{C}), 7.16 (ddd, 2H, ³J=8 Hz, 7 Hz, ⁴J=1 Hz, H_{c}); ESI-MS: m/z=567.15 [(M-CO₂H-2PF₆)⁺] (calcd for C₃₀H₂₂N₆Ru⁺: m/z=567.09). Anal. Calcd for C₃₁H₂₂F₁₂N₆O₂P₂Ru.H₂O: C, 40.49; H, 2.63; N, 9.14. Found: C, 40.58; H, 2.78; N, 8.73.

### (4) Preparation of [Ru(tpy-OMe)(tpy-CO₂H)](PF₆)₂ (Compound 3)

Solid KMnO₄ (963 mg, 30 eq) was added to [Ru(tpy-OMe)(tpy-2-furyl)](NO₃)₂ (160 mg, 0.20 mmol) in 30 mL of water and stirred at room temperature for 12 h. The solvent was removed after filtration, and the solid was then pre-absorbed on silica. The target complex was collected as an orange band using column chromatography [SiO₂:(acetone:MeOH:sat. aq. KNO₃)(6:3:1)]. Following the removal of solvent, the solid was reconstituted in water, acidified using acetic acid and the product precipitated as the PF₆ salt using saturated aqueous NH₄PF₆ to yield 130 mg of the red product (yield=68%). ¹H NMR (400 MHz, CD₃OD): δ=9.24 (s, 2H, H_{E}), 8.65 (d, 2H, ³J=8 Hz, H_{A}), 8.62 (d, 2H, ³J=8 Hz, Hₐ), 8.51 (s, 2H, Hₑ), 7.98 (ddd, 2H, ³J=8 Hz, 7 Hz, ⁴J=1 Hz, H_{B}), 7.94 (ddd, 2H, ³J=8 Hz, 7 Hz, ⁴J=1 Hz, H_{b}), 7.49 (d, 2H, ³J=7 Hz, H_{D}), 7.38 (d, 2H, ³J=7 Hz, H_{d}), 7.24 (ddd, 2H, ³J=8 Hz, 7 Hz, ⁴J=1 Hz, H_{C}), 7.17 (ddd, 2H, ³J=8 Hz, 7 Hz, ⁴J=1 Hz, H_{c}) 4.36 (s, 3H, H_{f}); ESI-MS: m/z=597.12 [(M-CO₂H-2PF₆)⁺] (calcd for C₃₁H₂₃N₆ORu⁺: m/z=597.10). Anal. Calcd for C₃₂H₂₄F₁₂N₆O₃P₂Ru: C, 41.26; H, 2.66; N, 9.02. Found: C, 41.41; H, 3.16; N, 8.88.

### (5) Preparation of [Ru(tpy)(tpy-2-furyl)](PF₆)₂ (Compound 4)

Compound 4 was collected as a red band using column chromatography [SiO₂:(acetone:MeOH:sat. aq. KNO₃)(5:2:1)]. The solvent was removed and the product precipitated as the PF₆⁻ salt using saturated aqueous NH₄PF₆ to yield 230 mg of the red product (yield=61%). ¹H NMR (400 MHz, CD₃CN): δ=8.97 (s, 2H, H_{E}), 8.76 (d, 2H, ³J=8 Hz, H_{A}), 8.62 (d, 2H, ³J=8 Hz, Hₐ), 8.50 (d, 2H, ³J=8 Hz, Hₑ), 8.41 (t, 1H, ³J=8 Hz, H_{f}), 7.97-7.87 (m, 5H, H_{B}, H_{b}, H_{H}), 7.62 (d, 1H, ³J=4 Hz, H_{F}), 7.43 (d, 2H, ³J=7 Hz, H_{D}), 7.34 (d, 2H, ³J=7 Hz, H_{d}), 7.16 (m, 4H, H_{C}, H_{c}), 6.87 (dd, 1H, ³J=4 Hz, 2 Hz, H_{G}); ESI-MS: m/z=778.94 [(M-PF₆)⁺] (anal. calcd for C₃₄H₂₄F₆N₆OPRu⁺: m/z=779.07). Anal. Calcd for C₃₄H₂₄F₁₂N₆OP₂Ru.H₂O: C, 43.37; H, 2.78; N, 8.93. Found: C, 43.29; H, 2.90; N, 8.54.

### (6) Preparation of [Ru(tpy-OMe)(tpy-2-furyl)](PF₆)₂ (Compound 5)

Compound 5 was collected as a red band using column chromatography [SiO₂:(acetone:MeOH:sat. aq. KNO₃)(5:2:1)]. The solvent was removed and the product precipitated as the PF₆⁻ salt using saturated aqueous NH₄PF₆ to yield 250 mg of the red product (yield=65%). ¹H NMR (400 MHz, CD₃CN): δ=8.95 (s, 2H, H_{E}), 8.61 (d, 2H, ³J=8 Hz, H_{A}), 8.49 (d, 2H, ³J=8 Hz, Hₐ), 8.33 (s, 2H, Hₑ), 7.97-7.86 (m, 5H, H_{B}, H_{b}, H_{H}), 7.60 (d, 1H, ³J=4 Hz, H_{F}), 7.42 (d, 2H, ³J=7 Hz, H_{D}), 7.38 (d, 2H, ³J=7 Hz, H_{d}), 7.19 (ddd, 2H, ³J=8 Hz, 7 Hz, ⁴J=1 Hz, H_{C}), 7.12 (ddd, 2H, ³J=8 Hz, 7 Hz, ⁴J=1 Hz, H_{c}) 6.86 (dd, 1H, ³J=4 Hz, 2 Hz, H_{G}), 4.31 (s, 3H, H_{f}); ESI-MS: m/z=809.05 [(M-PF₆)⁺] (calcd for C₃₅H₂₆F₆N₆O₂PRu⁺: m/z=809.08). Anal. Calcd for C₃₅H₂₆F₁₂N₆O₂P₂Ru: C, 44.08; H, 2.75; N, 8.81. Found: C, 44.37; H, 3.05; N, 9.02.

### (7) Preparation of [Ru(dpb-OMe)(tpy)]PF₆ (Compound 8)

Compound 8 was collected as the first purple band via column chromatography [SiO₂:(acetone:MeOH:sat. aq. KNO₃ (2:1:1))]. The solvent was removed and the product precipitated as the PF₆⁻ salt using saturated aqueous NH₄PF₆ to yield 120 mg of a deep red/purple product (yield=40%). ¹H NMR (400 MHz, CD₃OD): δ=8.87 (d, 2H, H_{E}), 8.54 (d, 2H, ³J=8 Hz, H_{A}), 8.26 (t, 1H, ³J=8 Hz, H_{F}), 8.17 (d, 2H, ³J=8 Hz, Hₐ), 8.00 (s, 2H, Hₑ), 7.71 (ddd, 2H, ³J=8 Hz, 7 Hz, ⁴J=1 Hz, H_{B}), 7.61 (ddd, 2H, ³J=8 Hz, 7 Hz, ⁴J=1 Hz, H_{b}), 7.17 (d, 2H, ³J=7 Hz, H_{D}), 6.99 (ddd, 2H, ³J=8 Hz, 7 Hz, ⁴J=1 Hz, H_{C}), 6.97 (d, 2H, ³J=7 Hz, H_{d}), 6.66 (ddd, 2H, ³J=8 Hz, 7 Hz, ⁴J=1 Hz, H_{c}) 4.00 (s, 3H, H_{f}); ESI-MS: m/z=596.18 [(M-PF₆)⁺] (anal. calcd for C₃₂H₂₄N₅ORu⁺: m/z=596.10). Anal. Calcd for C₃₂H₂₄F₆N₅OPRu.2H₂O: C, 49.49; H, 3.63; N, 9.02. Found: C, 49.29; H, 3.33; N, 8.73.

### (8) Preparation of [Ru(dpb)(tpy-2-furyl)]PF₆ (Compound 9)

Compound 9 was collected as a purple band using column chromatography [basic Al₂O₃:acetone saturated with KPF₆ and ascorbic acid)]. After removal of the solvent, the product suspended in water, filtered and then washed with Et₂O to yield 170 mg of a red product (yield=53%). ¹H NMR (400 MHz, CD₃CN): δ=8.98 (s, 2H, H_{E}), 8.54 (d, 2H, ³J=8 Hz, H_{A}), 8.25 (d, 2H, ³J=8 Hz, Hₑ), 8.13 (d, 2H, ³J=8 Hz, Hₐ), 7.90 (d, 1H, ³J=2 Hz, H_{H}), 7.70 (ddd, 2H, ³J=8 Hz, 7 Hz, ⁴J=1 Hz, H_{B}), 7.58 (ddd, 2H, ³J=8 Hz, 7 Hz, ⁴J=1 Hz, H_{b}), 7.52 (d, 1H, ³J=4 Hz, H_{F}), 7.46 (t, 1H, ³J=8 Hz, H_{f}), 7.11 (d, 2H, ³J=7 Hz, H_{D}), 7.09 (d, 2H, ³J=7 Hz, H_{d}), 6.94 (ddd, 2H, ³J=8 Hz, 7 Hz, ⁴J=1 Hz, H_{C}), 6.83 (dd, 1H, ³J=4 Hz, 2 Hz, H_{G}), 6.64 (ddd, 2H, ³J=8 Hz, 7 Hz, ⁴J=1 Hz, H_{c}); ESI-MS: m/z=632.14 [(M-PF₆)⁺] (anal. calcd for C₃₅H₂₄N₅ORu⁺: m/z=632.10). Anal. Calcd for C₃₅H₂₄F₆N₅OPRu.2H₂O: C, 51.73; H, 3.47; N, 8.62. Found: C, 51.30; H, 3.27; N, 8.93.

### (9) Preparation of [Ru(dpb-OMe)(tpy-2-furyl)]PF₆ (Compound 10)

Compound 10 was collected as a purple band using column chromatography [basic Al₂O₃:acetone saturated with KPF₆ and ascorbic acid)]. The solvent was removed, suspended in water, then filtered and washed with Et₂O to yield 190 mg of a purple solid (57%). ¹H NMR (400 MHz, CD₃CN): δ=8.98 (s, 2H, H_{E}), 8.53 (d, 2H, ³J=8 Hz, H_{A}), 8.13 (d, 2H, ³J=8 Hz, Hₐ), 7.97 (s, 2H, Hₑ), 7.90 (d, 1H, ³J=2 Hz, H_{H}), 7.70 (ddd, 2H, ³J=8 Hz, 7 Hz, ⁴J=1 Hz, H_{B}), 7.57 (ddd, 2H, ³J=8 Hz, 7 Hz, ⁴J=1 Hz, H_{b}), 7.52 (d, 1H, ³J=4 Hz, H_{F}), 7.13 (d, 2H, ³J=7 Hz, H_{D}), 7.07 (d, 2H, ³J=7 Hz, H_{d}), 6.96 (ddd, 2H, ³J=8 Hz, 7 Hz, ⁴J=1 Hz, H_{C}), 6.82 (dd, 1H, ³J=4 Hz, 2 Hz, H_{G}), 6.62 (ddd, 2H, ³J=8 Hz, 7 Hz, ⁴J=1 Hz, H_{c}) 4.32 (s, 3H, H_{f}); ESI-MS: m/z=662.18 [(M-PF₆)⁺] (anal. calcd for C₃₆H₂₆N₅O₂Ru⁺: m/z=662.11). Anal. Calcd for C₃₆H₂₆F₆N₅O₂PRu.2H₂O: C, 51.31; H, 3.59; N, 8.31. Found: C, 50.83; H, 3.29; N, 8.11.

### Properties of Compounds

The following section describes certain tests and their results in order to confirm the properties of the compounds of Example 1.

### (1) Physical Methods

Electrochemical measurements were performed under anaerobic conditions. Electrochemical measurements were made with a Princeton Applied Research VersaStat™ 3 potentiostat using dry solvents, a Pt working electrode, a Ag reference electrode, and 0.1 M NBu₄BF₄ supporting electrolyte. Potentials were initially referenced to an internal ferrocene (Fc) standard; however, potentials reported herein are referenced to a normal hydrogen electrode (NHE) on the premise that the (Fc/Fc⁺) couple occurs at +0.640 V vs NHE in MeCN.³⁵ Electronic spectroscopic data were collected on MeCN solutions using a Cary™ 5000 UV-vis Spectrophotometer (Varian™).

### (2) DFT Calculations

Density functional theory (DFT) calculations were carried out using B3LYP (Becke's three-parameter exchange functional (B3) and the Lee-Yang-Parr correlation functional (LYP)) and the LanL2DZ basis set. All geometries were fully optimized in the ground states (closed-shell singlet Sₒ). Time-dependent density functional theory (TD-DFT) calculations were performed with a spin-restricted formalism to examine low-energy excitations at the ground-state geometry (output files are provided as Supporting Information). All calculations were carried out with the Gaussian 03W™ software package.

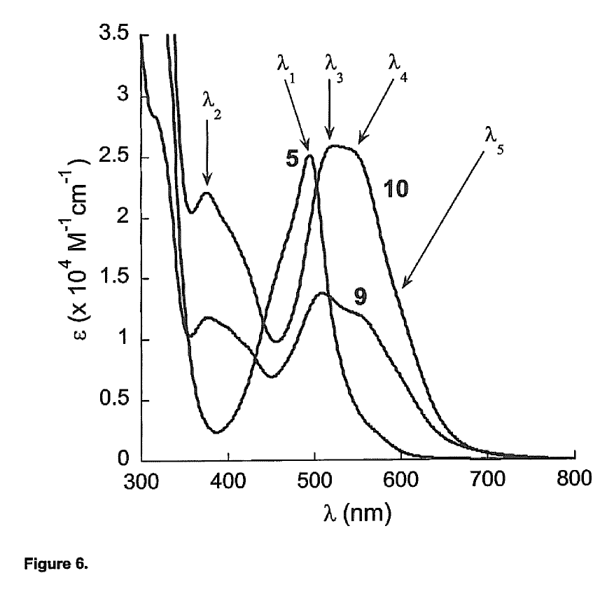

B3LYP/LanL2DZ DFT calculations were carried out on all Compounds to aid in the determination of the electronic structure, while TD-DFT calculations on optimized geometries in MeCN were employed to model the corresponding absorption spectra for all compounds. The correlation of theory to the UV-vis spectra shown in FIG. 6 is confined to transitions occurring over the 350-700 nm range. The experimental data and the TD-DFT results show distinct differences between analogous non-cyclometalating and cyclometalating compounds (e.g. Compounds 5 and 10). As shown in the UV-vis absorption spectrum of Compound 5 in FIG. 6, the dominant feature in the visible region is a narrow MLCT absorption band centered at 495 nm (λ₁). TD-DFT calculations for Compound 5 indicate that this transition arises primarily from the promotion of an electron from the d_{xz} metal orbital (HOMO) to the π* orbital of the tpy-2-furyl ligand (LUMO).

Upon ligation of an analogous cyclometalating ligand (i.e., dpb-OMe instead of tpy-OMe), the UV-vis absorption changes in two distinct ways: (i) a red-shift and broadening of the low-energy transitions; and (ii) the appearance of a new higher-energy absorption band near 400 nm. We note that the HOMO of the cyclometalated compounds contain significant ligand character on the central phenyl ring of the dpb-R¹ ligand. Consequently, absorption bands over the 350-700 nm range represent transitions with mixed-metal-ligand-to-ligand and intraligand charge-transfer (ILCT) character. Because the latter makes a lower relative contribution to the spectra, these bands will be broadly defined as MLCT bands herein for brevity; however, a full listing of the transitions are provided in the Supporting Information. The absorption bands for Compound 10 centered at 523 nm arise largely from two dominant MLCT transitions characterized as HOMO-1→LUMO+1 (λ₄) and HOMO-2→LUMO+1 (λ₃). These transitions correspond to the promotion of electrons from the d_{xz} and d_{xy} metal orbitals to the π* system of the tpy-2-furyl ligand, respectively. The lower-energy shoulder at ˜600 nm (λ₅) is ascribed to a MLCT process involving the promotion of an electron from the mixed metal-ligand HOMO to the LUMO derived of the it system of the tpy-2-furyl ligand. The high-energy transitions centered below 400 nm (λ₂) are due to MLCT transitions from the d_{yz} orbital to the high-energy π* level of the cyclometalating dpb-OMe ligand.

### (3) ESI-MS and ¹H NMR Spectroscopy

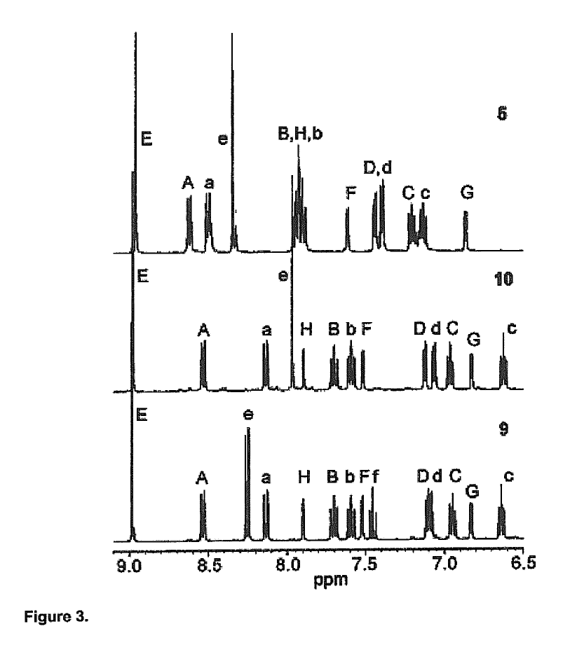

The identities of the Compounds were verified by ESI-MS and ¹H NMR spectroscopy. The spectra provided in FIG. 3 show the significance of cyclometalation and, to a lesser extent, the effects of —OMe substitution on the tpy ligand opposite the 2-furyl-substituted tpy (e.g., Compounds 5 and 10). Upon cyclometalation, there are significant upfield shifts in all of the aromatic cyclometalating ligand protons. The polypyridyl ligand and the 2-furyl substituent protons (H_{H}, H_{F}, H_{G}) experience modest upfield shifts consistent with the increased electron density on the metal center and the π-accepting nature of the polypyridyl ligands. The addition of the —OMe substituent has a less dramatic effect on the chemical shift. There are strong upfield shifts on the phenyl ring protons (Hₑ), and small upfield perturbations in the adjacent pyridyl ring (H_{d}).

### (4) Electrochemical and Electronic Absorption Spectroscopy

The electrochemical and electronic absorption properties of Compounds 1-10 were examined in acetonitrile by cyclic voltammetry and UV-vis spectroscopy, respectively. Measured redox couples and absorption data for Compounds 1-6 are reported in Table 1, and Compounds 7-10 are collected in Table 2. All Compounds exhibit well-resolved redox couples over the +2 to −2 V (vs NHE) range.

TABLE 1
Summary of select electrochemical and spectroscopic data for compounds 1-6.

| | UV-vis data | | redox data (V vs NHE)^{a} | | |
|---|---|---|---|---|---|
| | λₘₐₓ^{b} | ε (×10⁴ M⁻¹ | | | |
| compound | (nm) | cm⁻¹) | E_{1/2} (ox) | E_{1/2} (red) | |
| [Ru(tpy)₂](PF₆)₂ (1) | 476 | 1.54 | 1.52 | −1.02 | −1.27 |
| [Ru(tpy)(tpy-CO₂H)](PF₆)₂ (2) | 479 | 1.95 | 1.55 | −1.05 | −1.33 |
| [Ru(tpy-OMe)(tpy-CO₂H)](PF₆)₂ (3) | 484 | 1.94 | 1.48 | −1.08 | −1.32 |
| [Ru(tpy)(tpy-2-furyl)](PF₆)₂ (4) | 488 | 2.23 | 1.49 | −0.93 | −1.07 |
| [Ru(tpy-OMe)(tpy-2-furyl)](PF₆)₂ (5) | 495 | 2.50 | 1.41 | −1.01 | −1.26 |
| [Ru(tpy-2-furyl)₂](PF₆)₂ (6) | 500 | 3.19 | 1.48 | −0.96 | −1.20 |

^{a}Data collected using 0.1M NBu₄BF₄ MeCN solutions at 100 mV/s and referenced to a [Fc]/[Fc]⁺ internal standard followed by conversion to NHE ([Fc]/[Fc]⁺ vs NHE = +0.64 V).³⁵
^{b}λₘₐₓ of lowest-energy band.

TABLE 2
Summary of select electrochemical and
spectroscopic data for compounds 7-10.

| | | | redox data | |
|---|---|---|---|---|
| | UV-vis data | | (V vs NHE)^{a} | |
| | λₘₐₓ^{b} | ε (×10⁴ M⁻¹ | E_{1/2} | E_{1/2} |
| Compound | (nm) | cm⁻¹) | (ox) | (red) |
| [Ru(tpy)(dpb)]PF₆ (7) | 500 | 1.17 | 0.75 | −1.32 |
| [Ru(tpy)(dpb-OMe)]PF₆ (8) | 535 | 1.59 | 0.62 | −1.31 |
| [Ru(tpy-2-furyl)(dpb)]PF₆ (9) | 509 | 1.36 | 0.76 | −1.26 |
| [Ru(tpy-2-furyl)(dpb-OMe)]PF₆ (10) | 523 | 2.59 | 0.62 | −1.26 |

^{a}Data collected using 0.1M NBu₄BF₄ MeCN solutions at 100 mV/s and referenced to a [Fc]/[Fc]⁺ internal standard followed by conversion to NHE ([Fc]/[Fc]⁺ vs NHE = 0.64 V),³⁵ unless otherwise stated.
^{b}λₘₐₓ of lowest-energy band.
^{c}Potentials reported vs. [Fc]/[Fc]⁺ with NBU₄PF₆ as a supporting electrolyte, tabulated here vs NHE by adding +0.64 V.

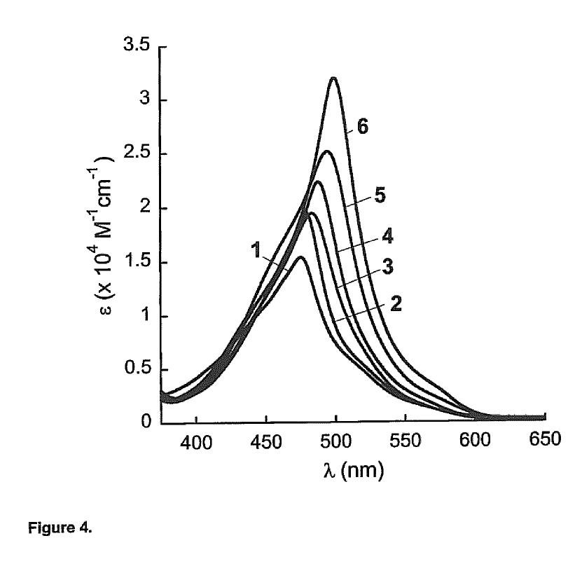

The UV-vis absorption spectra for Compounds 1-6 are provided in FIG. 4; corresponding extinction coefficients and maxima corresponding to the lowest-energy excitation transitions are listed in Table 1. A common feature for the entire series is the presence of intense bands in the ultraviolet region between 250-350 nm (not shown), which are assigned as spin-allowed ¹(π-π*) ligand transitions. Examination of the lower energy bands reveals systematic trends that are consistent with the modest structural modifications. For instance, increasing the conjugation within the series results in a red-shift of the λₘₐₓ with the concomitant increase in molar extinction coefficient. The first reversible oxidation process, which corresponds to a R^{II/III} couple, is also sensitive to the nature of the tpy substituents. For instance, the addition of a single —OMe group decreases the oxidation potential by approximately 70-80 mV. Installation of the electron-rich, aromatic 2-furyl group decreases the oxidation potential by ca. 20 mV, while the electron-withdrawing CO₂H group increases the oxidation potential by ca. 50 mV. The ligand-based reductions are also sensitive to ligand modification. The general trend that emerges from Compounds 1-6 is that extending the conjugation of the ligand shifts the LUMO to lower energy, while increasing electron density on the metal center raises the energy of the HOMO, and to a lesser extent the LUMO.

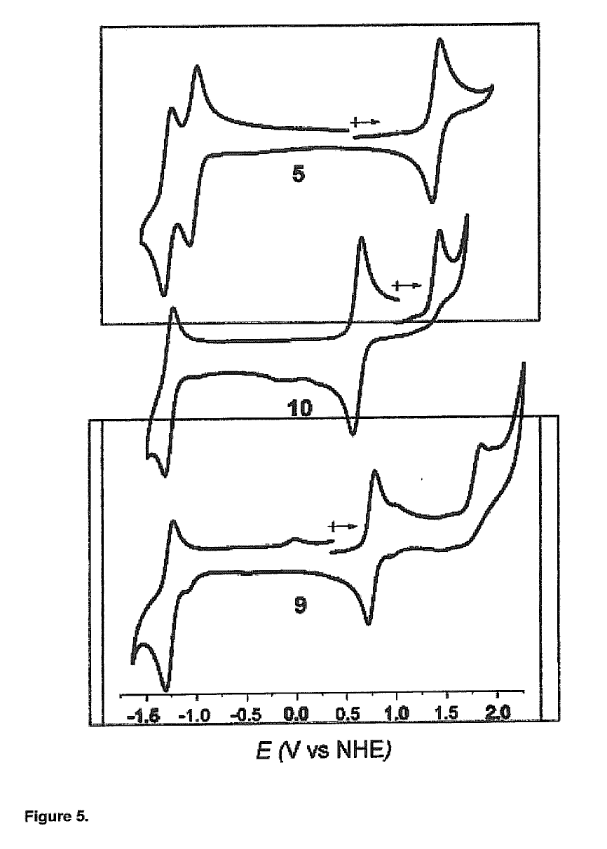

Electrochemical and spectroscopic data for Compounds 7-10 are listed in Table 2. Representative cyclic voltammograms are also included in FIG. 5. Unlike for the tpy series, there is only one observed reversible reduction wave within the solvent window for the cyclometalated analogues, which is assigned to the tpy ligand. Increasing conjugation on the tpy ligand results in a lower-energy ligand-based reduction process. The reversible oxidation wave is ascribed to a R^{II/III} process, and is significantly affected by cyclometalation; i.e., lower oxidation potential. In contrast to the tpy series, the addition of the —OMe substituent to the cyclometalating ligand results in a substantial increase in electron density at the metal causing a 130-140 mV decrease in the R^{II/III} oxidation potential. All of the cyclometalated compounds also have an irreversible oxidation at higher potentials (see FIG. 5; data not tabulated) attributed to ligand-based decomposition. A ligand decomposition process is supported by the observation that the metal-based potential is sensitive to the presence of electron-donating groups.

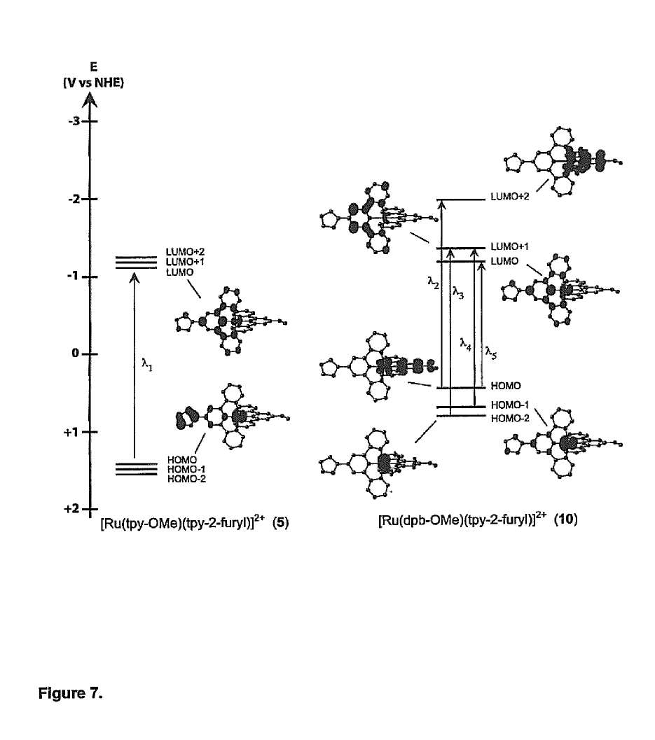

The UV-vis absorption data with extinction coefficients and maxima corresponding to the lowest-energy excitation bands are listed in Table 2. An examination of the lower energy bands reveals some significant differences relative to the tpy series. For instance, dissymmetry in the electronic structure of the heteroleptic cyclometalated compounds results in the broadening of the spectral features (FIG. 6), which is substantiated by the TD-DFT calculations (FIG. 7). Compounds 5 and 10 exhibit similar molar extinction coefficients, but there is a significant broadening and a bathochromic shift for the spectrum corresponding to cyclometalated complex 10 which is caused by the loss of degeneracy of the occupied metal d orbitals. The absorption profiles of 9 and 10 are similar, but the molar absorption for the latter is nearly two-fold greater, which underscores the extent to which the —OMe substituent alters the light harvesting properties of this molecule.

### Example 2

### Preparation of Compounds

The following examples describe the synthesis and testing of embodiments of cyclometalated Ru(II) dye compounds (Compounds 11-20) of Example 2. These embodiments should not be construed as limiting the present invention. The preparation of other cyclometalated Ru (II) dye compounds is within the purview of a person skilled in the art.

Compounds 11-20 are as follows:

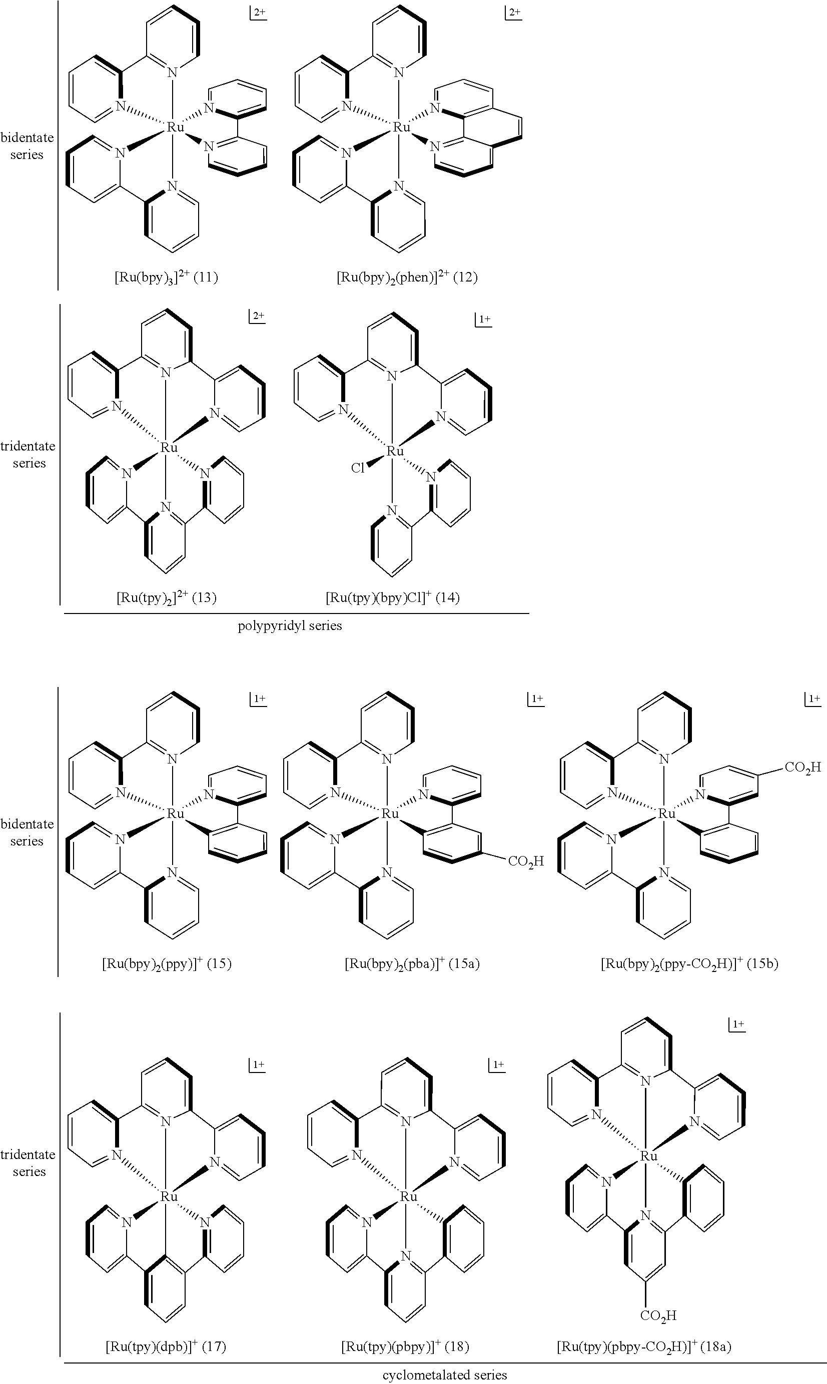

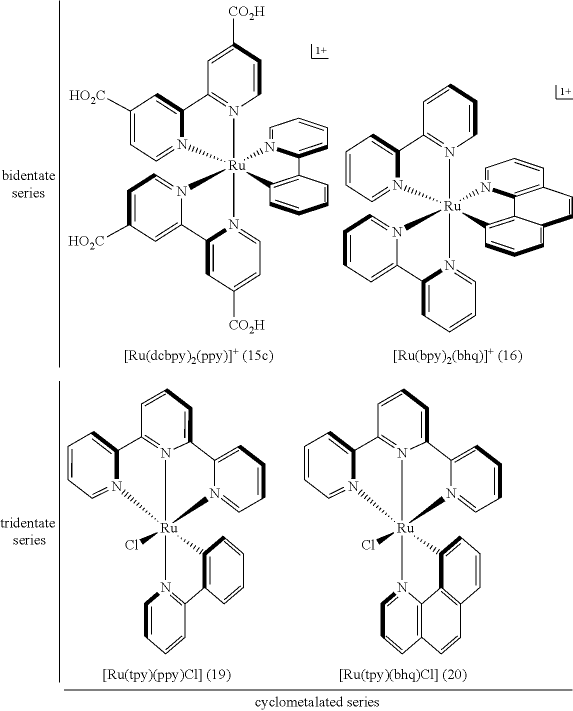

All manipulations were performed using solvents passed through an MBraun solvent purification system prior to use; chloroform (CHCl₃) and tetrahydrofuran (THF) solvents were analytical grade (without stabilizer). All reagents were purchased from Aldrich, except for RuCl₃ (Pressure Chemical Company), bpy and dcbpy (Alfa Aesar), and Hpba (Synchem). Purification by column chromatography was carried out using silica (Silicycle: Ultrapure Flash Silica) or basic alumina (Fluka). Analytical thin-layer chromatography (TLC) was performed on aluminum-backed sheets pre-coated with silica 60 F254 adsorbent (0.25 mm thick; Merck, Germany), or with plastic-backed sheets pre-coated with basic alumina 200 F254 adsorbent (0.25 mm thick, Selecto Scientific: Georgia, USA) and visualized under UV light. Ligands Hdpb,³³ Hpbpy,³⁴ Hpbpy-CO₂H, ³²[Ru(ppy)(MeCN)₄](PF₆)³⁵ and Compounds 11 [Broomhead 1981], 12 [Huang et al. 2006], 13 [Schubert et al. 2001], 14 [Yang et al. 2005], 15 [Constable et al. 1986], 16 [Reveco et al. 1986], 17 [Schubert et al. 2001], and 18 [Barigelletti et al. 1993] were prepared according to published procedures (with additional purification by column chromotagraphy).

### (1) Preparation of 2-bromopyridine-4-carboxylic acid

To 1.84 g (11.6 mmol) of KMnO₄ in 10 mL of H₂O was added 0.65 mL (5.8 mmol) of 2-bromo-4-methylpyridine via syringe. The solution was refluxed for 1 hr, after which 1.25 equivalents (1.15 g; 7.25 mmol) of KMnO₄ was added. After an additional 2 hr reflux, 1.25 equivalents of KMnO₄ was added and stirred overnight to produce a dark solution containing a black suspension. After filtration through celite, the clear aqueous layer was washed with 3×20 mL of ethyl acetate. The aqueous layer was brought to a pH of 4 using 1M HCl to precipitate out 237 mg of a white solid (yield=20.3%). ESI-MS: m/z 199.7 (calcd for M⁺199.9) ¹H NMR (DMSO-d₆): δ 7.84 (dd, 1H, ³J=5 Hz, ⁴J=1 Hz), 7.96 (s, 1H), 8.59 (d, 1H, ³J=5 Hz), 14.02 (vbr, 1H).

### (2) Preparation of 2-phenylpyridine-4-carboxylic acid (Hppy-CO₂H)

To a flask containing 237 mg (1.18 mmol) of 2-bromopyridine-4-carboxylic acid, 213 mg (1.75 mmol) of phenylboronic acid, and 26 mg (0.12 mmol) of Pd(OAc)₂ was added a large excess of K₂CO₃ (1627 mg, 11.79 mmol) in 20 mL H₂O. The solution was refluxed overnight to produce a dark black suspension that was filtered to yield a dark black filtrate, which was then acidified to a pH of 4 using 2M HCl to precipitate 110 mg of a white solid (yield=47%). ¹H NMR (DMSO-d₆): δ 7.50 (m, 3H), 7.77 (dd, 1H, ³J=5 Hz, ⁴J=1 Hz), 8.12 (d, 2H, ³J=5 Hz), 8.28 (s, 1H), 8.85 (d, 1H, ³J=5 Hz), 13.85 (vbr, 1H)

### (3) Preparation of 1,3-Bis(2-pyridyl)benzene (Hdpb)

A THF (150 mL) solution containing 1.95 g (8.30 mmol) of 1,3-dibromobenzene and 0.077 g (0.66 mol) of tetrakis(triphenylphosphine)palladium(0) was charged with 38 mL (17 mmol) of a 0.5 M THF solution of 2-pyridylzinc bromide. The solution was refluxed for 14 hrs, then cooled and quenched with a saturated aqueous NaHCO₃ solution (100 mL) and washed with aqueous EDTA (100 mL). The crude product was extracted with diethyl ether (2×100 mL), and the organic fractions were collected and dried over MgSO₄. The solvent was removed in vacuo to afford an oil that was purified by column chromatography (silica; EtOAc:DCM 1:9) to afford 1.8 g of a pale yellow oil product (yield=94%). GC-MS: m/z 232. ¹H NMR (CDCl₃): δ 7.06 (t, 2H, ³J=6 Hz), 7.46 (t, 1H, ³J=8 Hz), 7.57 (t, 2H, ³J=7 Hz), 7.68 (d, 2H, ³J=8 Hz), 7.96 (d, 2H, ³J=8 Hz), 8.59 (s, 1H), 8.60 (d, 2H, ³J=7 Hz).

### (4) Preparation of 6-phenyl-2,2′-bipyridine (Hpbpy)

A solution of phenyl lithium (3.60 mL, 6.48 mmol) was injected into 20 mL of toluene containing 1.00 g (6.43 mmol) of bpy. The red solution was refluxed overnight to produce a purple solution that was cooled to room temperature, and then transferred into a separatory funnel and washed with 30 mL of water. The aqueous layer was washed with dichloromethane (3×15 mL), and the organic layers were pooled and dried with MgSO₄. After filtration, the solvent was removed in vacuo to yield a red oil, and then purified by column chromatography (silica; Et₂O:hexanes 3:7). The solvent was removed in vacuo to yield 562 mg of an off-white crystalline product (yield=37.7%). GC-MS: m/z 232 (calcd for {M}⁺ 232). ¹H NMR (CDCl₃): δ 7.30 (ddd, 1H, ³J=8 Hz, ³J=8 Hz, ⁴J=1 Hz), 7.42 (dt, 1H, ³J=7 Hz, ⁴J=1 Hz), 7.49 (tt, 2H, ³J=7 Hz, ⁴J=1 Hz), 7.76 (dd, 1H, ³J=8 Hz, ⁴J=1 Hz), 7.82 (dt, 1H, ³J=8 Hz, ⁴J=1 Hz), 7.88 (t, 1H, ³J=8 Hz), 8.13 (dt, 2H, ³J=8 Hz, ⁴J=1 Hz), 8.35 (dd, 1H, ³J=8 Hz, ⁴J=1 Hz), 8.62 (dt, 1H, ³J=8 Hz, ⁴J=1 Hz), 8.67 (ddd, 1H, ³J=5 Hz, ³J=5 Hz, ⁴J=1 Hz).

### (5) Preparation of [Ru(bpy)₂(ppy)]PF₆ (Compound 15)

A flask containing 196 mg (0.377 mmol) of Ru(bpy)₂Cl₂, 152 mg (0.784 mmol) of AgBF₄, and 0.16 mL (1.1 mmol) of 2-phenylpyridine in 30 mL of dichloromethane was stirred at reflux for 21 hrs. The solution was left to cool to room temperature, filtered through celite to afford a dark red-purple filtrate and concentrated to 5 mL. After the addition of 200 mL of hexanes, the solution was left to stand at 4° C. overnight to afford a dark red-purple solid that was filtered and washed with water (3×15 mL). The solid was dissolved in acetonitrile to carry out anion metathesis using a saturated aqueous NH₄PF₆ solution to render a dark purple precipitate. This solid was collected and washed with water (3×15 mL) and diethyl ether (3×15 mL) to afford 150 mg of a purple solid (yield=55.0%). ¹H NMR (CD₃CN): 6.41 (dd, 1H, ³J=7 Hz, ⁴J=1 Hz), 6.82 (dt, 1H, ³J=5 Hz, ⁴J=1 Hz), 6.89 (dt, 1H, ³J=5 Hz, ⁴J=1 Hz), 6.92 (ddd, 1H, ³J=7 Hz, 5 Hz, ⁴J=1 Hz), 7.20 (m, 3H), 7.40 (ddd, 1H, ³J=8 Hz, 5 Hz, ⁴J=1 Hz), 7.55 (ddd, 1H, ³J=5 Hz, ⁴J=2 Hz, ⁵J=1 Hz), 7.68 (ddd, 1H, ³J=8 Hz, 7 Hz, ⁴J=1 Hz), 7.72 (dd, 1H, ³J=5 Hz, ⁴J=1 Hz, ⁵J=1 Hz), 7.82 (m, 6H), 7.97 (ddd, 1H, ³J=8 Hz, 7 Hz, ⁴J=1 Hz), 8.01 (d, 1H, ³J=8 Hz), 8.05 (ddd, 1H, ³J=5 Hz, ⁴J=2 Hz, ⁵J=1 Hz), 8.29 (d, 1H, ³J=8 Hz), 8.31 (d, 1H, ³J=8 Hz), 8.35 (d, 1H, ³J=8 Hz), 8.45 (d, 1H, ³J=8 Hz). ESI-MS: m/z 568.0 (calcd for {M⁺} 568.1) Anal. Calcd. for C₃₁H₂₄F₆N₅PRu: C, 52.25; H, 3.39; N, 9.83. Found: C, 53.06; H, 3.66; N, 9.80.

### (6) Preparation of [Ru(bpy)₂]PF₆ (Compound 15a)

To a flask containing 95 mg (0.48 mmol) of 3-(pyridin-2-yl)benzoic acid and 20 mg (0.50 mmol) of NaOH was added 30 mL of degassed aqueous methanol solution (H₂O:MeOH 1:5 v/v). The reagents were stirred until all components were dissolved and then transferred to a flask containing 188 mg (0.362 mmol) of Ru(bpy)₂Cl₂ and 180 mg (0.93 mmol) AgBF₄. The reaction mixture was heated at reflux for 18 hrs, cooled, and then filtered through celite to afford a dark red/purple filtrate. The solvent was removed in vacuo and then passed through a silica column (MeCN:KNO_{3(aq)} 7:1 v/v), followed by anion exchange with a saturated aqueous NH₄PF₆ methanolic solution to produce 52 mg of a red precipitate (yield=19%). ¹H NMR (CD₃CN): 6.61 (d, 1H, ³J=8 Hz), 6.98 (dt, 1H, ³J=7 Hz, 6 Hz, ⁴J=1 Hz), 7.17-7.25 (m, 3H), 7.39, (dd, 1H, ³J=8 Hz, ⁴J=2 Hz), 7.42 (dt, 1H, ³J=8 Hz, ⁴J=1 Hz), 7.60 (d, 1H, ³J=5 Hz), 7.69-7.75 (m, 3H), 7.78-7.87 (m, 4H), 7.95 (d, 1H, ³J=6 Hz), 7.99 (dt, 1H, ³J=8 Hz, ⁴J=2 Hz), 8.14 (d, 1H, ³J=8 Hz), 8.31 (d, 1H, ³J=7 Hz), 8.33 (d, 1H, ³J=7 Hz), 8.38 (d, 1H, ³J=8 Hz), 8.41 (d, 1H, ⁴J=2 Hz), 8.46 (d, 1H, ³J=8 Hz), 9.08 (vbr, 1H). ESI-MS: m/z 612.1 (calcd for {M⁺} 612.1) Anal. Calcd. for C₃₂H₂₄F₆N₅O₂PRu+0.5H₂O: C, 50.20; H, 3.29; N, 9.15. Found: C, 50.29; H, 3.49; N, 9.07.

### (7) Preparation of [Ru(bpy)₃(ppy-CO₂H)]NO₃ (Compound 15b)

To a flask containing 110 mg (0.553 mmol) of Hppy-CO₂H, 275 mg (0.529 mmol) of Ru(bpy)₂Cl₂, 183 mg (1.08 mmol) of AgNO₃, and 28 mg (0.70 mmol) of NaOH was added 30 mL of a degassed aqueous methanol solution (H₂O:MeOH 1:5 v/v). The reaction mixture was heated at reflux for 18 hrs, cooled, and then filtered through celite to afford a dark red/orange filtrate. The solvent was removed in vacuo and then passed through a silica column (acetone:MeOH:KNO_{3 (sat, aq)} 2:1:1). The sample was passed through a silica column (MeOH:CHCl₃ 3:1) a second time and 56 mg of a red-purple product was obtained after recrystallization from CH₂Cl₂ and hexanes (yield=14%). ¹H NMR (CD₃OD): 6.42 (dd, 1H, ³J=7 Hz, ⁴J=1 Hz), 6.79 (td, 1H, ³J=7 Hz, ⁴J=1 Hz), 6.89 (td, 1H, ³J=7 Hz, ⁴J=1 Hz), 7.19-7.28 (m, 3H), 7.31, (dd, 1H, ³J=6 Hz, ⁴J=2 Hz), 7.46 (ddd, 1H, ³J=7 Hz, 5 Hz, ⁴J=1 Hz), 7.58 (d, 1H, ³J=6 Hz, ⁴J=1 Hz), 7.72-7.91 (m, 7H), 8.02 (ddd, 1H, ³J=8 Hz, 8 Hz, ⁴J=1 Hz), 8.10 (ddd, 1H, ³J=5 Hz, ⁴J=2 Hz, ⁵J=1 Hz), 8.41 (d, 1H, ³J=8 Hz), 8.45 (d, 1H, ⁴J=1 Hz), 8.45 (d, 1H, ³J=8 Hz), 8.51 (d, 1H, ³J=8 Hz), 8.61 (d, 1H, ³J=8 Hz). ESI-MS: m/z 612.0 (calcd for {M⁺} 612.1) ¹³C NMR (CD₃OD with 1 drop of NaOD): 194, 172, 169, 159, 159, 158, 157, 156, 151, 151, 151, 150, 147, 146, 138, 136, 136, 135, 135, 130, 128, 128, 127, 127, 125, 125, 125, 124, 124, 123, 122, 119. Anal. Calcd. for C₃₂H₂₄N₆O₅Ru+CH₃OH: C, 56.17; H, 4.00; N, 11.91. Found: C, 57.45; H, 4.40; N, 10.38.

### (8) Preparation of [Ru(dcbpy)₂(ppy)]PF₆ (Compound 15c)

To a flask containing 99 mg (0.17 mmol) of [Ru(ppy)(CH₃CN)₄]PF₆, 87 mg (0.36 mmol) of 2,2′-bipyridine-4,4′-dicarboxylic acid, and 29 mg (0.73 mmol) of sodium hydroxide was added 30 mL of degassed aqueous methanol solution (H₂O:MeOH 1:5 v/v). The reaction mixture was then refluxed for 3 hr. The solvent was then removed in vacuo to afford a dark purple solid, which was purified using silica column chromatography (MeOH:CHCl₃ 3:1). The dark purple fraction was isolated, reconstituted in 20 mL of MeOH and then drawn out of solution using 100 mL of Et₂O to afford 104 mg of a purple solid (yield=80.0%). ¹H NMR (CD₃OD plus a drop of NaOD): 6.39 (dd, 1H, ³J=7 Hz, ⁴J=1 Hz), 6.81 (dt, 1H, ³J=7 Hz, ⁴J=1 Hz), 6.89 (dt, 1H, ³J=7 Hz, ⁴J=1 Hz), 6.95 (ddd, 1H, ³J=7 Hz, 6 Hz, ⁴J=1 Hz), 7.54 (d, 1H, ³J=5 Hz), 7.60 (dd, 1H, ³J=7 Hz, ⁴J=1 Hz), 7.63 (dd, 1H, ³J=6 Hz, ⁴J=2 Hz), 7.65 (dd, 1H, ³J=6 Hz, ⁴J=2 Hz), 7.70 (dt, 1H, ³J=7 Hz, ⁴J=2 Hz), 7.76 (d, 1H, ³J=6 Hz), 7.83-7.87 (m, 3H), 7.88 (dt, 1H, ³J=5 Hz, ⁴J=1 Hz), 8.06 (d, 1H, ³J=8 Hz), 8.13 (d, 1H, ³J=6 Hz), 8.86 (s, 1H), 8.87 (s, 1H), 8.94 (s, 1H), 9.02 (s, 1H). ESI-MS: m/z 744.01 (calcd for RuC₃₅H₂₁N₅O₈ 744.07) Anal. Calcd. for C₃₅H₂₄F₆N₅O₈PRu+5H₂O: C, 42.95; H, 3.50; N, 7.16. Found: C, 42.93; H, 3.67; N, 7.27.

### (9) Preparation of [Ru(bpy)₂(bhq)]PF₆ (Compound 6)

A flask containing 232 mg (0.446 mmol) of Ru(bpy)₂Cl₂, 204 mg (1.05 mmol) of AgBF₄ and 242 mg (1.35 mmol) of Hbhq in 30 mL of dichloromethane was stirred at reflux for 19 hr. After the solution was cooled, filtered through celite and concentrated to 5 mL, 200 mL of hexanes was added and the solution was left to stand at 4° C. overnight to afford a dark red-purple solid. The solid isolated after purification by column chromatography (silica; MeCN:KNO₃ 7:1), followed by anion exchange with a saturated aqueous NH₄PF₆ methanolic solution, filtered and washed with ether (3×15 mL) to afford 57.0 mg of the product (yield=17.0%). NMR (CD₃CN): 6.69 (dd, 1H, ³J=7 Hz, ⁴J=1 Hz), 6.95 (d, 1H, ³J=9 Hz), 7.03-7.07 (m, 1H), 7.10, (d, 1H, ³J=9 Hz), 7.27 (m, 3H), 7.43 (d, 1H, ³J=8 Hz), 7.48 (ddd, 1H, ³J=7 Hz, 6 Hz, ⁴J=1 Hz), 7.64 (d, 1H, ³J=6 Hz), 7.74 (m, 3H), 7.87 (m, 4H), 8.01-8.04 (m, 2H), 8.22 (d, 1H, ³J=8 Hz), 8.31 (d, 1H, ³J=8 Hz), 8.37 (m, 2H), 8.50 (d, 1H, ³J=8 Hz). ESI-MS: m/z 592.0 (calcd for {M⁺} 592.1) Anal. Calcd. for C₃₃H₂₄F₆N₅PRu+CH₂Cl₂+CH₃OH: C, 49.25; H, 3.54; N, 8.20. Found: C, 49.75; H, 3.33; N, 7.70.

### (10) Preparation of [Ru(tpy)(dpb)]PF₆ (Compound 7)

A flask containing 37.1 mg (84.2 μmol) of Ru(tpy)Cl₃ and 19.4 mg (83.5 μmol) of Hdpb was charged with 12 mL of an aqueous methanol solution (MeOH:H₂O 5:1 v/v) containing 4 drops of N-ethylmorpholine and stirred at reflux for 4 hr. The solution was cooled to room temperature and filtered. The purple filtrate was then stirred with excess NH₄PF₆ for 5 min, followed by the removal of solvent in vacuo. The resultant purple solid was dissolved in a minimal amount of THF and loaded onto a silica column (CH₂Cl₂:Et₂O 9:1 v/v). The red band was isolated and recrystallized from CH₂Cl₂ and hexanes to yield 24.2 mg of a black crystalline product (yield=40.5%). ¹H NMR (CD₃CN): δ 6.65 (ddd, 2H, ³J=6 Hz, ³J=6 Hz, ⁴J=1 Hz), 6.95 (dt, 2H, ³J=7), 7.02 (d, 2H, ³J=5 Hz), 7.11 (d, 2H, ³J=5 Hz), 7.46 (t, 1H, ³J=8 Hz), 7.60 (dt, 2H, ³J=8 Hz, ⁴J=1 Hz), 7.69 (dt, 2H, ³J=8 Hz, ⁴J=1 Hz), 8.14 (d, 2H, ³J=8 Hz), 8.24 (t, 1H, ³J=8 Hz), 8.25 (d, 2H, ³J=8 Hz), 8.42 (d, 2H, ³J=8 Hz), 8.74 (d, 2H, ³J=8 Hz). ESI-MS: m/z 566.13 (calcd for {M}⁺566.09). Anal. Calcd. for C₃₁H₂₂F₆N₅PRu: C, 52.40; H, 3.12; N, 9.86. Found: C, 52.18; H, 3.38; N, 9.40.

### (11) Preparation of [Ru(tpy)(pbpy)]PF₆ (Compound 8)

A flask containing 75.0 mg (170 μmol) of Ru(tpy)Cl₃ and 39.8 mg (170 μmol) of pbpy was charged with 4 drops of N-ethylmorpholine in 24 mL of aqueous methanol (5:1 MeOH:H₂O v/v). The reaction mixture was stirred for 4 hrs at reflux, and then filtered after being cooled to room temperature. Excess NH₄PF₆ was added to the filtrate and stirred for 5 mins, followed by removal of the solvent in vacuo. The resultant purple solid was dissolved in a minimum volume of THF and passed through a silica column (CH₂Cl₂:THF:Et₂O 5:5:2 v/v). The purple band was isolated and recrystallized from CH₂Cl₂ and hexanes to afford 50.8 mg of a dark purple product (yield=42.0%). ¹H NMR (CD₃CN): δ 5.68 (d, 1H, ³J=8 Hz), 6.51 (t, 1H, ³J=8 Hz), 6.73 (dt, 1H, ³J=8 Hz, ⁴J=1 Hz), 7.05 (dt, 3H, ³J=8 Hz, ⁴J=1 Hz), 7.43 (m, 3H), 7.75 (dt, 2H, ³J=8 Hz, ⁴J=1 Hz), 7.81 (dd, 1H, ³J=8 Hz, ⁴J=1 Hz), 7.86 (dt, 1H, ³J=8 Hz, ⁴J=1 Hz), 8.04 (t, 1H, ³J=8 Hz), 8.07 (t, 1H, ³J=8 Hz), 8.23 (dd, 1H, ³J=8 Hz, ⁴J=1 Hz), 8.40 (dd, 3H, ³J=8 Hz, ⁴J=1 Hz), 8.43 (d, 1H, ³J=8 Hz), 8.59 (d, 2H, ³J=8 Hz). ESI-MS: m/z 566.08 (calcd for {M}⁺566.09). Anal. Calcd. for C₃₁H₂₂F₆N₅PRu: C, 52.40; H, 3.12; N, 9.86. Found: C, 52.24; H, 3.42; N, 9.66.

### (12) Preparation of [Ru(tpy)(pbpy-CO₂H)]PF₆ (Compound 8a)

A flask containing 75.0 mg (170 μmol) of Ru(tpy)Cl₃, 39.8 mg (170 μmol) of pbpy-CO₂H, and 4 drops of N-ethylmorpholine in 24 mL of a degassed aqueous methanol solution (H₂O:MeOH 1:5 v/v) was stirred at reflux for 4 hrs. After the purple solution was cooled to room temperature and filtered, excess NH₄PF₆ was added to the filtrate and stirred for 5 mins. The solvent was removed in vacuo and the resultant purple solid was redissolved in THF and passed through a silica column (MeCN:sat KNO₃ 7:3 v/v). The purple band was isolated and the solvent was removed in vacuo. The purple solid was dissolved in 400 mL of hot water, and the product was precipitated upon addition of excess KPF₆. The solid was filtered, washed with water and recrystallized from CH₂Cl₂ and hexanes to afford 40.8 mg of a deep purple crystalline product (yield=35.6%). ¹H NMR (CD₃CN): δ 5.74 (d, 1H, ³J=8 Hz), 6.54 (dt, 1H, ³J=8 Hz, ⁴J=1 Hz), 6.75 (dt, 1H, ³J=8 Hz, ⁴J=1 Hz), 7.02 (m, 3H), 7.42 (d, 1H, ³J=8 Hz), 7.47 (d, 1H), 7.74 (dt, 2H, ³J=8 Hz, ⁴J=1 Hz), 7.85 (dt, 1H, ³J=8 Hz, ⁴J=1 Hz), 7.93 (d, 2H, ³J=8 Hz), 8.07 (t, 1H, ³J=8 Hz), 8.40 (d, 2H, ³J=8 Hz), 8.61 (d, 3H, ³J=8 Hz), 8.74 (s, 1H), 8.94 (s, 1H). ESI-MS: m/z 610.05 (calcd for {M}⁺610.08). Anal. Calcd. for C₃₂H₂₂F₆N₅O₂PRu+1.33C₆H₁₄: C, 55.25; H, 4.71; N, 8.05. Found: C, 55.60; H, 4.43; N, 8.14.

### (13) Preparation of [Ru(tpy)(ppy)Cl] (Compound 9)

A flask containing 86.3 mg (0.196 mmol) of Ru(tpy)Cl₃, 35.0 μL (0.245 mmol) of Hppy, and 4 drops of N-ethylmorpholine in 18 mL of an aqueous methanol solution (H₂O:MeOH 1:5 v/v) was stirred for 4 hrs at reflux. The solution was cooled to room temperature and then filtered. The dark purple precipitate was washed with 3×15 mL Et₂O to remove excess Hppy. The solid was dissolved in MeOH and filtered to remove impurities. The solvent was then removed in vacuo to yield a pure dark purple solid to afford 25.2 mg (yield=24.5%) of the product. ¹H NMR (CD₃OD; solution contains one drop of a saturated methanolic solution of ascorbic acid to avoid aerial oxidation): δ 5.62 (d, 1H), 6.35 (t, 1H), 6.56 (t, 2H), 7.26 (m, 2H), 7.60 (m, 1H), 7.67 (m, 2H), 7.83 (t, 2H), 7.93 (t, 1H), 7.99 (t, 1H), 8.23 (d, 1H), 8.39 (d, 2H), 8.48 (d, 2H), 9.31 (s, 1H). Anal. Calcd. for C₂₆H₁₉ClN₄Ru+H₂O: C, 57.62; H, 3.91; N, 10.34. Found: C, 57.81; H, 3.72; N, 10.27. ESI-MS: m/z 566.13 (calcd for {M}⁺ 566.09).

### (14) Preparation of [Ru(tpy)(bhq)Cl] (Compound 20)

A flask containing 100 mg (0.228 mmol) of Ru(tpy)Cl₃, 61.2 mg (0.341 mmol) of Hbhq, and 4 drops of N-ethylmorpholine in 18 mL aqueous methanol (5:1 MeOH:H₂O v/v) was stirred for 4 hrs at reflux. The solution was cooled to room temperature and then filtered. The purple precipitate was washed with Et₂O (3×15 mL) to remove excess Hbhq, then reconstituted in MeOH. Solvent was removed in vacuo to afford 17.1 mg of a dark purple solid (yield=13.7%). ¹H NMR (CD₃OD; solution contains one drop of a saturated methanolic solution of ascorbic acid to avoid aerial oxidation): δ 5.88 (s, 1H), 6.75 (t, 1H), 7.01 (d, 1H), 7.11 (d, 2H), 7.50 (d, 2H), 7.72 (d, 1H), 7.78 (t, 3H), 7.96 (t, 2H), 8.39 (d, 2H), 8.51 (d, 3H), 9.58 (s, 1H). ESI-MS: m/z 547.95 (calcd for {M}⁺ 548.03), 513.03 (calcd for {M⁺-Cl⁻} 513.07). Anal. Calcd. for C₂₈H₁₉ClN₄Ru+CH₃OH: C, 60.05; H, 4.00; N, 9.66. Found: C, 60.27; H, 3.62; N, 10.04.

### Properties of Compounds

The following section describes certain tests and their results in order to confirm the properties of the compounds of Example 2.

### (1) Physical Methods

Electrochemical measurements were performed under anaerobic conditions with a Princeton Applied Research VersaStat 3 potentiostat using dry solvents, Pt working and counter electrodes, a Ag pseudoreference electrode, and 0.1 M NBu₄BF₄ supporting electrolyte. Potentials were initially referenced to an internal ferrocene (Fc) standard; however, potentials reported herein are referenced to a normal hydrogen electrode (NHE) on the premise that the [Fc]/[Fc]⁺ couple occurs at +0.640 V vs NHE in MeCN [Pavlishchuk et al. 2000]. ¹H spectra were recorded in dry deuterate solvents at 400 MHz on a Bruker AV 400 instrument at ambient temperatures unless otherwise stated. Chemical shifts (δ) are reported in parts per million (ppm) from high- to low-field and referenced to residual non-deuterated solvents. Standard abbreviations indicating multiplicity are used as follows: vbr=very broad; d=doublet; m=multiplet; s=singlet; t=triplet. Electronic spectroscopic data were collected on MeCN solutions using a Cary 5000 UV-vis spectrophotometer (Varian). Steady-state emission spectra were obtained at room temperature using an Edinburgh Instruments FLS920 Spectrometer equipped with a Xe900 450W steady state xenon arc lamp, TMS300-X excitation monochromator, TMS300-M emission monochromator, Hamamatsu R2658P PMT detector and corrected for detector response. Elemental analysis (EA) and electrospray ionization mass spectrometry (ESI-MS) data were collected at the University of Calgary.

The experimental data and TD-DFT results indicate a number of transitions within the absorption manifold of the cyclometalated complexes. This broad envelope arises primarily because: (i) a set of π* orbitals associated with the cyclometalated ligand are located at slightly higher energies than those of the polypyridyl ligands that comprise the LUMO; and (ii) there is a breakdown in degeneracy of the d orbitals, which comprise the highest-energy occupied orbitals, in the presence of a single Ru—C bond. The electron density of the HOMO for all cyclometalated complexes is found primarily on the metal, but there is also significant cyclometalating ligand character. Cognizant of this feature, we broadly classify all electronic transitions that emanate from a metal-based HOMO—even with partial ligand character—to a ligand-based π* orbital as a MLCT transition for the sake of brevity.

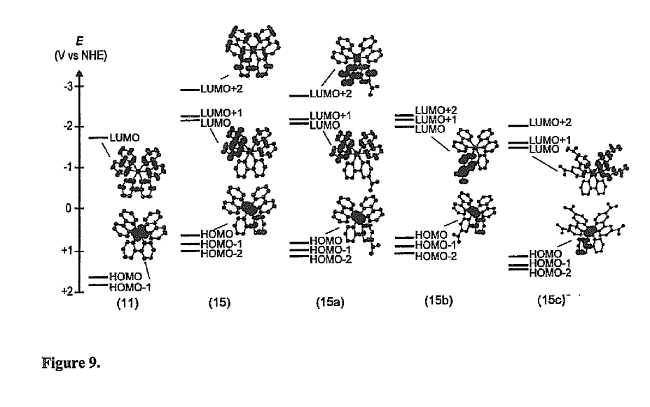

In the case of Compound 15, the highest occupied orbitals follow the order d_{xy} (HOMO-2)<d_{yz} (HOMO-1)<d_{xz} (HOMO) (FIG. 9); the unoccupied metal orbitals reside significantly higher in energy relative to the polypyridyl congeners. The LUMO and LUMO+1 levels are delocalized over the π* system of both bpy ligands, while the π* orbitals of all three ligands contributes to the LUMO+2 level (which lies 0.75 eV above the LUMO). The lowest-energy maximum in the UV-vis spectrum of 5 is therefore assigned as a MLCT process involving Ru→bpy transitions, while the features at ca. 400 nm involve an excited state delocalized over the π* system of the ppy⁻ ligand. The presence of bhq⁻ in place of the ppy⁻ ligand has no notable effect on the electronic structure of the ground- and excited-states.

The only structural difference between Compounds 15 and 15a is the presence of a carboxylic acid attached to the phenyl ring of the ppy ligand, which results in the stabilization of the HOMO by +0.10 eV. With the —CO₂H group attached to the pyridine ring in Compound 15b, however, the π* orbitals of the pyridine portion of the ppy-CO₂H ligand are pulled to lower energies than those associated with the bpy ligands. Because the electron density of the LUMO in Compound 15 is delocalized over the π* of the bpy ligands, electron-withdrawing substituents on these ligands are most effective in lowering the LUMO. Consequently, Compound 15c provides the most red-shifted absorption profile of all the compounds measured in this study. We also note that ground-state oxidation potential of Compound 15c is calculated to be ca. +1.0.

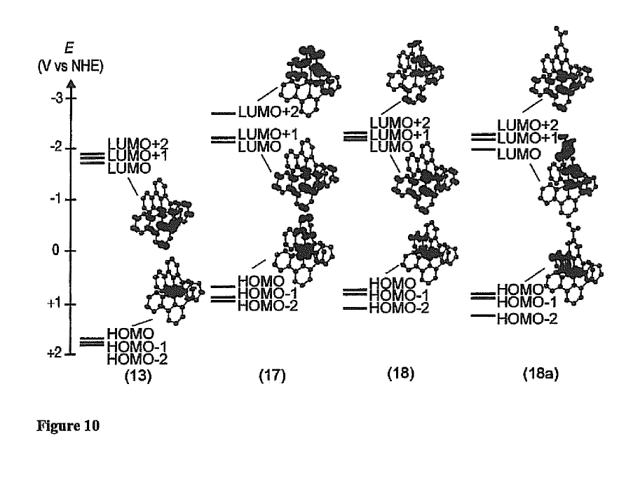

An examination of the [Ru(tpy)(L)]^{z} series reveals that the HOMO electron density of Compound 13 is localized primarily on the metal d_{xy} orbital (degenerate d_{xz} and d_{yz} orbitals lie slightly lower in energy), with some ligand character distributed over both tpy ligands (FIG. 10). The substitution of a single tpy ligand with either pbpy⁻ or dpb⁻ affects the ordering of the d orbitals and destabilizes the σ* orbitals substantially. We again note that there is significant ligand contribution (up to 50%) to the HOMO levels. The principal contribution to the lowest-energy band centered at 500 nm involves HOMO-1/HOMO-2→LUMO/LUMO+1 transitions that correspond to the promotion of electrons from degenerate d_{yz} and d_{xy} orbitals to the tpy ligand. The shoulder at shorter wavelengths is ascribed to a Ru→dpb⁻ MLCT process; i.e., HOMO-1→LUMO+2. The features occurring between 350 and 450 nm are assigned as MLCT transitions involving the dpb⁻ ligand. The reduced symmetry of Compound 18 forces the Ru—C_{aryl} σ-bond to be oriented perpendicular to the z-axis, which affects the degeneracy of the energy levels and increases the number of observed transitions. This arrangement results in the reordering of the highest occupied metal orbitals to follow d_{xz} (HOMO-2)<d_{yz} (HOMO-1)˜d_{xy} (HOMO). The experimental UV-vis spectrum indicates two features on the low-energy tail of the MLCT band: the lower energy transition at 630 nm is predominantly a Ru→tpy CT process, while the features at 565 nm and 513 nm are dominated by transitions from the Ru center to the tpy ligand and the pyridine rings of the pbpy ligand. Higher energy transitions around 400 nm are assigned as MLCT bands to the orbitals delocalized over the entire pbpy⁻ ligand. The —CO₂H substituent on the pbpy⁻ ligand of Compound 18a stabilizes the orbital centered on the cyclometalating ligand such that the (pbpy-CO₂H)⁻ ligand becomes the LUMO. The tpy ligand remains only 0.22 eV higher in energy in this scenario, so the lowest-energy absorption band involves MLCT transitions to both tpy and the pyridine rings of (pbpy-CO₂H)⁻.

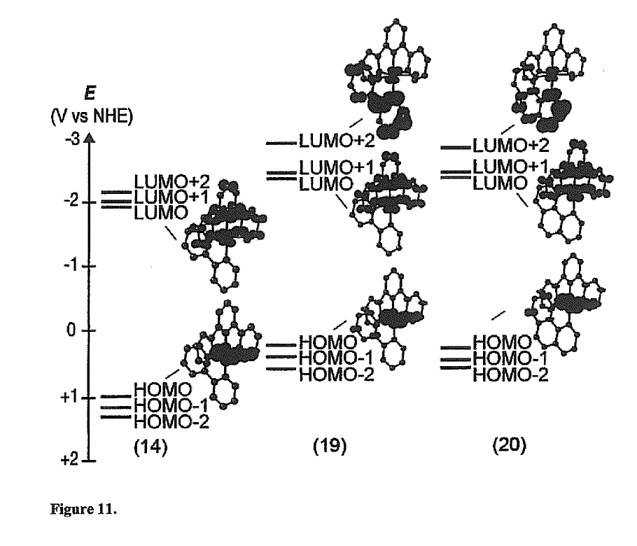

The electronic structure for the [Ru(tpy)(L)Cl]^{z} series differs substantially because of the π* interaction of the d orbitals with the Cl⁻ ligand. This repulsion forces the HOMO (d_{xy}) and HOMO-1 (d_{yz}) levels higher in energy leaving the d, orbital as the HOMO-2 in Compound 14; the low-lying unoccupied orbitals are delocalized over the tpy and bpy ligands (FIG. 11). The broad absorption band is due to a MLCT transition to both the tpy and bpy ligands, with the shoulder observed at lower energies arises primarily from a Ru→tpy transition. The stable cyclometalated Compounds 19 and 20 exist with the Ru—C_{aryl} bond trans to the halide, which drives the metal-halide it orbitals to even higher energies. The bonding scheme of the CAN analogues renders the principle axis parallel to the Ru—C_{aryl} bond; thus, the d orbitals are reordered such that the d_{yz} and d_{xz} orbitals comprise the HOMO and HOMO-1 levels, respectively. The d_{xy} orbital is found at HOMO-2 because of the absence of electron repulsion with the filled p orbital of the Cl⁻ ligand. The LUMO and LUMO+1 levels are localized on the tpy ligand, with the cyclometalating ligand contributing to the LUMO+2 level (which lie ca. 0.50 and 0.35 eV higher in energy than the LUMO for Compounds 19 and 20, respectively). Transitions from the metal orbitals to the tpy ligand and the pyridine ring of ppy⁻ are responsible for the broad low-energy MLCT bands, while the bands centered at ˜400 nm involve charge-transfer to orbitals spanning the entire ppy⁻ ligand. The minor difference in spectral features between Compounds 19 and 20 is due primarily to a slight stabilization of the HOMO in Compound 20.

### (2) ESI-MS and ¹H NMR Spectroscopy

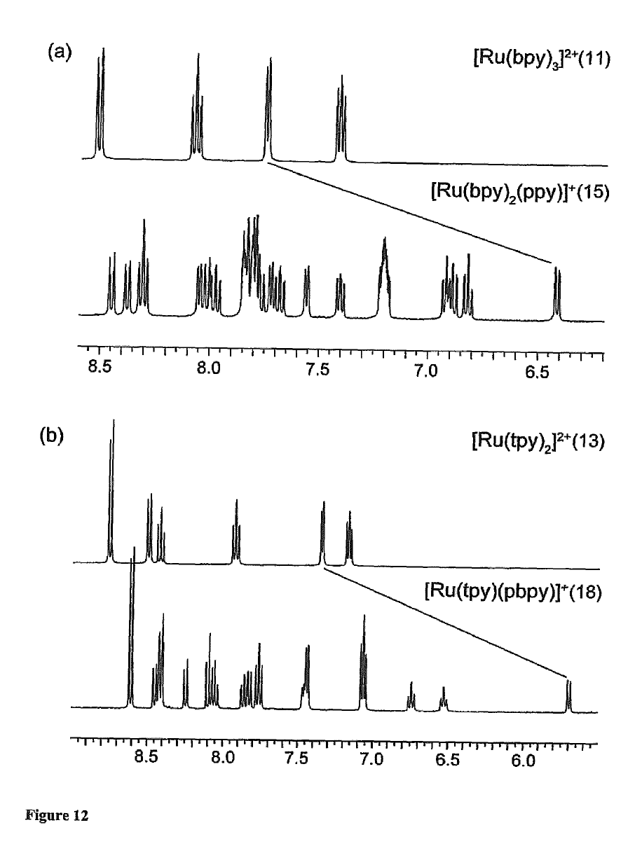

The identities of the complexes were verified by ESI-MS and ¹H NMR spectroscopy. ¹H NMR spectroscopy is a convenient tool for monitoring these reactions since cyclometalation has a dramatic influence on the proton ortho or para to the C_{aryl} atom bound to the Ru center. In the case of Compound 15, for instance, the proton resonance ortho to the C_{aryl} atom at 6.41 ppm is shifted upfield by 1.34 ppm relative to the analogous proton in Compound 11 at 7.75 ppm (FIG. 12). The other protons situated on the phenyl ring are also moved upfield, but to a lesser extent. The spectrum of Compound 15 is more complicated than that of Compound 11 due to the collapse of D₃ symmetry; thus, a 2D COSY experiment was used to aid in the assignment of the proton signals. A more pronounced effect is observed in the tridentate series: the signal corresponding to the resonance adjacent to the organometallic bond in Compound 18 is found at 5.68 ppm (an upfield shift of 1.66 ppm relative to Compound 13), with the meta and para protons at 6.52 and 6.73 ppm, respectively. The upfield proton is more shielded in Compound 18 than in Compound 15 because of the interaction with the central pyridine ring of the proximate tpy ligand. The same degree of shielding of the aromatic protons is not observed for Compound 17 because there are no protons ortho to the C_{aryl} atom bound to the Ru center; however, the signal para to this C_{aryl} atom is drawn upfield by 0.96 ppm relative to the proton at the 4′ position of the tpy ligand in Compound 13.

Special care must be taken for the acquisition of ¹H NMR spectra of the [Ru(tpy)(ĈN)Cl]⁺ compounds because of their susceptibility to oxidation in solution, but we were able to suppress adventitious oxidation by adding ascorbic acid to the solution to record satisfactory spectra for both Compounds 19 and 20. These spectra again reveal upfield aromatic protons at 5.62 and 5.88 ppm, respectively, to indicate that cyclometalation has occurred. The spectra also indicate that of the two possible isomers present in solution, only the isomer with the Ru—C_{aryl} bond trans to the Cl⁻ ligand is observed for both Compounds 19 and 20. The shielding of the proton ortho to the Ru—C_{aryl} bond by the tpy ligand in 19 leads to a resonance at 5.62 ppm, while the proton ortho to the Ru—N bond in the same ligand is pushed downfield (9.31 ppm) because of the interaction with the halide ligand.

### (3) Electrochemical Behavior.

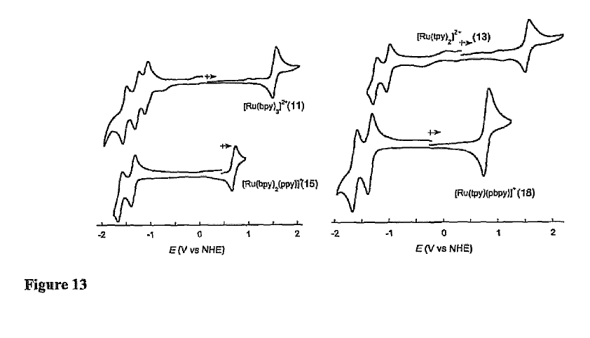

The electrochemical properties of Compounds 11-20 were examined by cyclic voltammetry; the observed redox couples are collected in Table 3. Most compounds exhibit well-resolved redox couples (i_{p,a}/i_{p,c}≈1) over the −2 to +2 V (vs NHE) range, and resting potentials occurred within 0.5 V of 0 V vs NHE; representative cyclic voltammograms are provided in FIG. 13. The redox behavior of Compound 11 consists of a reversible metal-based oxidation process at +1.52 V and a ligand-based reduction wave at −1.09 V. Both oxidation and reduction waves for Compound 15, however, are shifted substantially to more negative values, with observed oxidation and reduction signals at +0.70 V and −1.36 V, respectively. As in the case of the non-cyclometalated congeners, the oxidation process is assigned as a R^{II/III} couple, and the reduction process is confined to the polypyridyl ligand. The incorporation of the σ-bond leads to a shift of the oxidation and reduction processes by ca. −0.7 V and −0.3 V, respectively. These shifts are ascribed to the additional electron density on the metal center and the disparity of the overall charge of the complexes (e.g., Compound 11 is dicationic, while Compound 15 is monocationic). The shift of the reduction potentials upon cyclometalation is a consequence of enhanced π-backbonding to the pyridyl units resulting from the enhanced electron density at the metal center. These same trends are observed for each independent series, [Ru(bpy)₂(L)]^{z}, [Ru(tpy)(L)]^{z}, and [Ru(tpy)(L)Cl]^{z}.

The diminution of electron density at the metal upon attaching a —CO₂H group to the ppy⁻ ligand is corroborated by shift in oxidation potential of Compound 15a to more positive values with virtually no effect on the first reduction potential relative to Compound 15. The first oxidation wave for Compound 15b, on the other hand, is only slightly effected, while the first reduction wave remains static. These results, collectively, are consistent with electron density in the HOMO partially delocalized over both the phenyl ring and the metal center, and the first reduction wave is associated with the bpy ligands (vide infra). The acquisition of electrochemical data for Compound 15c was hampered by poor solubility, and the monodeprotonated form could not be recorded in a solvent with a broad electrochemical window. Data for Compound 15c, less a proton, therefore had to be recorded in MeOH, which only revealed a single redox process over the −1 to +1 V range: a reversible oxidation couple at +0.76 V (a solvent correction was applied by referencing this couple to the oxidation potential of Compound 15 in MeOH against [Fc]/[Fc]⁺). Since a Ft has been shown to shift the oxidation potential by ca. +0.2 V in a related system,³⁰ we speculate that the first oxidation potential of Compound 15c occurs at ca. +0.96 V. While an accurate value could not be determined in our hands, the higher oxidation potential of Compound 15c relative to Compound 15 clearly indicate that the —CO₂H anchoring groups effectively reduce the electron density at the metal site.

The reduction and oxidation waves do not vary significantly over the Compounds 11-13, but the Cl⁻ ligand present in Compound 14 induces a negative shift in all observed thermodynamic potentials. The effect of attaching a strongly σ-donating aryl group to the metal already ligated to the π-donating Cl⁻ anion produces the lowest oxidation potentials of all species measured in this study. For instance, the oxidation potentials for Compounds 19 and 20 are ca. 0.6 V lower than that of Compound 14, and ca. 1.1 V lower than the complexes containing six Ru—N bonds (i.e., Compounds 11-13).

TABLE 3
Electrochemical and Electronic Spectroscopy Data for Compounds 11-20.^{a}

| | E_{1/2} (V vs NHE) | | | λₘₐₓ^{b} | ε | λ_{cm}^{c} |
|---|---|---|---|---|---|---|
| compound | Eₒₓ₁ | E_{red1} | E_{red2} | (nm) | (×10⁴ M⁻¹ cm⁻¹) | (nm) |
| [Ru(bpy)₂(L)]^{Z} Series | | | | | | |
| [Ru(bpy)₃]²⁺ (11) | +1.52 | −1.09 | −1.29^{d} | 451 | 1.4 | 615 |
| [Ru(bpy)₂(phen)]²⁺ (12) | +1.52 | −1.08 | −1.28^{e} | 449 | 1.6 | 612 |
| [Ru(bpy)₂(ppy)]⁺ (15) | +0.70 | −1.36 | −1.62 | 546 | 1.0 | 800 |
| [Ru(bpy)₂(pba)]⁺ (15a) | +0.82 | −1.35 | −1.62 | 530 | 1.0 | 760 |
| [Ru(bpy)₂(ppy-CO₂H)]⁺ (15b) | +0.67 | −1.36 | −1.62 | 554 | 1.1 | 807 |
| [Ru(dcbpy)₂(ppy)]⁺ (15c) | -^{f} | -^{f} | -^{f} | 575 | -^{f} | -^{f} |
| | (+0.76^{g}) | | | (562^{g}) | (1.0^{g}) | (809^{g}) |
| [Ru(bpy)₂(bhq)]⁺ (16) | +0.73 | −1.34 | −1.58 | 543 | 0.84 | 784 |
| [Ru(tpy)(L)]^{Z} Series | | | | | | |
| [Ru(tpy)₂]²⁺ (13) | +1.52 | −1.02 | −1.27 | 476 | 1.5 | — |
| [Ru(tpy)(dpb)]⁺ (17) | +0.75 | −1.32 | −1.76^{h} | 500 | 1.2 | 705 |
| [Ru(tpy)(pbpy)]⁺ (18) | +0.73 | −1.40 | −1.68 | 513 | 1.3 | 708 |
| [Ru(tpy)(pbpy-CO₂H)]⁺ (18a) | +0.86 | −1.39 | −1.68^{h} | 515 | 1.2 | 716 |
| [Ru(tpy)(L)Cl]^{Z} Series | | | | | | |
| [Ru(tpy)(bpy)Cl]⁺ (14) | +1.05 | −1.20 | −1.33 | 482^{j} | 0.96^{j} | 729^{j} |
| [Ru(tpy)(ppy)Cl] (19) | +0.46ⁱ | −1.40ⁱ | −1.50ⁱ | 541^{j} | 0.34^{j} | 782^{j} |
| [Ru(tpy)(bhq)Cl] (20) | +0.48ⁱ | −1.37ⁱ | −1.53ⁱ | 537^{j} | 0.71^{j} | 725^{j} |

^{a}All data recorded in MeCN at 298K unless otherwise specified; counterion is PF₆⁻ for all cationic complexes except 15b, which was measured as the NO₃⁻ salt; all values in table measured in our laboratories.
^{b}Only the lowest-energy λₘₐₓ is listed.
^{c}All data collected in deaerated solvent at ambient temperatures.
^{d}E_{1/2} (red3) is observed at −1.53 V;
^{e}Poorly resolved;
^{f}Poor solubility precluded collection of redox potentials, ε values, and λ_{cm}.
^{g}Corresponds to mono-deprotonated form of 15c; electrochemistry measured in MeOH and solvent correction applied using oxidation potential of 15 measured in MeOH against [Fc]/[Fc]⁺.
^{h}Irreversible (E_{p, c} is reported).
ⁱMeasured in DMF.
^{j}Measured in MeOH.

### (4) Electronic Spectroscopy.

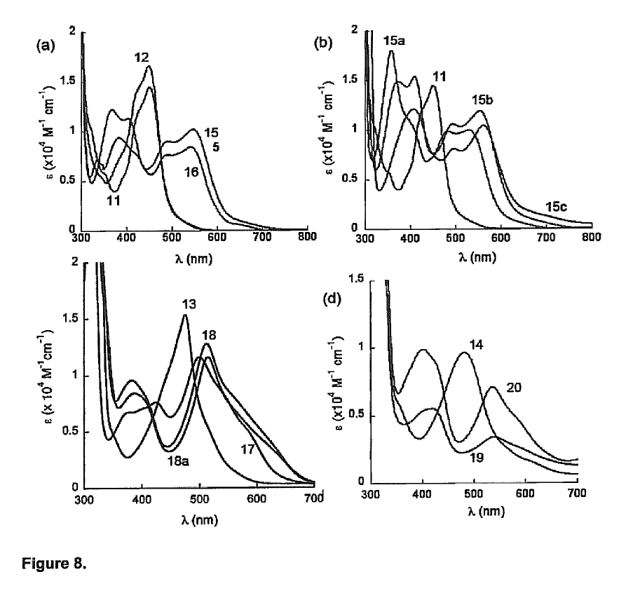

The UV-vis absorption spectra for Compounds 11-20 are provided in FIG. 8; the maxima corresponding to the lowest-energy excitation bands and the corresponding emission data are listed in Table 3. A common feature over the entire series is the presence of intense bands in the ultraviolet region between 300-350 nm (not shown), which are assigned as spin-allowed ¹(π-π*) ligand transitions. Examination of the lower energy bands reveals pronounced differences in the absorption profiles; namely, a substantial bathochromic shift and a larger spectral envelope upon cyclometalation (there are also extra features below 300 nm ascribed to intraligand π-π* transitions). For the bidentate series, the spectral maxima of the lowest-energy transitions for Compounds 15 and 16 are red-shifted by ca. 95 nm compared to Compounds 11 and 12. The lowering of the symmetry upon incorporation of a Ru—C σ-bond results in transitions that lead to a broader absorption envelope. Within the tridentate series, Compounds 17 and 18 are only shifted to longer wavelengths by 24-39 nm compared to Compound 13, but the molar absorptivity values, which are on the order of 15,000 M⁻¹cm⁻¹, are not diminished to the same extent as in the bidentate series. A feature that emerges in the spectra of the cyclometalated compounds is the set of intense bands over the 350-450 nm range. The extinction coefficients of these bands are consistent with significant MLCT character, and are ascribed to the population of excited states involving the cyclometalated ligands; the MLCT bands at >500 nm have excited states localized primarily to the polypyridyl ligands (vide infra).

The spectra of the [Ru(tpy)(L)Cl]^{z} series reveal the dramatic effect of Cl⁻ ligation on the electronic structure of these compounds. The λₘₐₓ value for Compound 14 is red-shifted by 30-57 nm compared to Compounds 11-13, a consequence of a destabilized HOMO due to the repulsion of the filled metal d orbitals with the filled p orbitals of the halide ligand. Substitution of bpy by either ppy⁻ or bhq⁻ produces an additional bathochromic shift of ca. 30 nm. The ε values of neutral complexes Compounds 19 and 20 are relatively low to Compound 14; however, the data may be affected by the low solubility of these complexes. Like the other cyclometalated complexes, intense bands are observed at 350-450 nm. In contrast to the [Ru(tpy)(L)]^{z} series, however, these transitions are more intense than the lowest-energy bands. This is aligned with the assignment that the lowest-energy excitation process involves excited states localized to the tpy ligand, while the transitions at ca. 400 nm involve excited-states associated with ppy⁻ or bhq⁻.

There are distinct spectral changes for the complexes containing the —CO₂H substituents that are consistent with the assignment of the transitions over the 350-700 nm range. In the case of 15a, for instance, the —CO₂H group results in a blue-shift of the lowest-energy band by 16 nm, and the band at ca. 400 nm by 8 nm. Both of these MLCT bands are red-shifted in the cases of Compounds 15b and 15c, with the lowest-energy transition observed for Compound 15c (λₘₐₓ at 575 nm). These trends are consistent with a LUMO derived of polypyridyl ligands, and a HOMO with electron density delocalized over both the metal and the aryl ring of the cyclometalating ligand (vide infra). Because an accurate ε value could not be obtained for Compound 15c due to solubility issues in a range of solvents, we provide data corresponding to the monodeprotonated form of Compound 15c for comparison (λₘₐₓ=562 nm).

Excitation at wavelengths defined by the absorption maximum of the lowest-energy excited states produced emission signals that were very weak for all cyclometalated compounds in this study. The room temperature spectra indicate a substantial Stokes shift for the entire series accompanied with poor quantum yields. According to the energy gap law, the destabilization of the HOMO provides non-radiative pathways to the ground state that suppresses fluorescence—a feature common to cyclometalated compounds.

As used herein, the terms, “comprises” and “comprising” are to be construed as being inclusive and open ended, and not exclusive. Specifically, when used in this specification including claims, the terms, “comprises” and “comprising” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

### REFERENCES

BARIGELLETTI, F.; FLAMIGNI, L.; BALZANI, V.; COLLIN, J. P.; SAUVAGE, J. P.; SOUR, A.; CONSTABLE, E. C.; THOMPSON, A. M. W. C. 1993. Journal of the Chemical Society, Chemical Communication. 942-944.
BESSHO, T.; YONEDA, E.; YUM, J.-H.; GUGLIELMI, M.; TAVERNELLI, I.; IMAI, H.; ROTHLISBERGER, U.; NAZEERUDDIN, M. K.; GRÄTZEL, M. 2009. New paradigm in molecular engineering of sensitizers for solar cell applications. Journal of the American Chemical Society. 131, 5930-5934.
BOMBEN, P.; ROBSON, K.; SEDACH, P.; BERLINGUETTE, C. 2009. On the viability of using cyclometalated Ru(II) complexes for light-harvesting applications. Inorganic Chemistry, in press.
BROOMHEAD, J. A. Y. C. G. 1981. Inorg. Synth. 127.
CHAMBERS, J.; EAVES, B.; PARKER, D.; CLAXTON, R.; RAY, P. S.; SLATTERY, S. J. 2006. Inductive influence of 4′-terpyridyl substituents on redox and spin state properties of iron(II) and cobalt(II) bis-terpyridyl complexes. Inorganica Chimica Acta. 359, 2400-2406.
CONSTABLE, E. C.; DUNPHY, E. L.; HOUSECROFT, C. E.; NEUBURGER, M.; SCHAFFNER, S.; SCHAPER, F.; BATTEN, S. 2007. Expanded ligands: bis(2,2:6,2-terpyridine carboxylic acid)ruthenium(II) complexes as metallosupramolecular analogues of dicarboxylic acids. Dalton Transactions. 38, 4323-4332.
CONSTABLE, E. C.; HOLMES, J. M. 1986. A cyclometalated analogue of tris(2,2′-bipyridine)ruthenium(II). Journal of Organometallic Chemistry. 301, 203-208.
GALOPPINI, “LINKERS FOR ANCHORING DYES . . . ” COORD CHEM REV, 2004, 248, 1283-1297
GRÄTZEL, M. 2005. Solar energy conversion by dye-sensitized photovoltaic cells. Inorganic Chemistry 44, 6841-6851.
HUANG, W.; OGAWA, T. 2006. Spontaneous resolution of Δ and Λ enantiomeric pair of [Ru(phen)(bby)₂](PF₆)₂ phen=1,10-phenanthroline, bpy=2,2′bipyridine) by conglomerate crystallization. Polyhedron. 25, 1379-1385.
HUSSON, J.; BELEY, M.; KIRSCH, G. 2003. A novel pathway for the synthesis of a carboxylic acid-functionalised Ru(II) terpyridine complex. Tetrahedron Letters. 44, 1767-1770.
ITO, S.; CHEN, P.; COMTE, P.; NAZEERUDDIN, M. K.; LISKA, P.; PECHY, P.; GRÄTZEL, M. 2007. Fabrication of screen-printing pastes from TiO₂ powders for dye-sensitized solar cells. Progress in Photovoltaics: Research and Applications. 15, 603-612.
JURIS, A.; BALZANI, V.; BARIGELLETTI, F.; CAMPAGNA, S.; BELSER, P, VON ZELEWSKY, A. 1988. Ru(II) polypiridine complexes: photophysics, photochemistry, electrochemistry, and chemiluminescence. Coordination Chemistry Reviews. 84, 85-277.
KEENE F. R. 1997 Stereochemistry and polymetallic ligand-bridged molecular assemblies. Coordination Chemistry Reviews. 166, 121-159.
MAESTRI, M.; ARMAROLI, N.; BALZANI, V.; CONSTABLE, E. C.; THOMPSON, A. M. W. C. 1995. Complexes of the Ruthenium(II)-2,2′:6′,2″-terpyridine Family. Effect of Electron-Accepting and -Donating Substituents on the Photophysical and Electrochemical Properties. Inorganic Chemistry. 34, 2759-2767.
MEDLYCOTT, E. A.; HANAN G. S. 2005. Designing tridentate ligands for ruthenium(II) complexes with prolonged room temperature luminescence lifetimes. Chemical Society Reviews. 34, 133-142.
NAZEERUDDIN, M. K.; PÉCHY, P.; RENOUARD, T.; ZAKEERUDDIN, S. M.; HUMPHRY-BAKER, R.; COMTE, P.; LISKA, P.; CEVEY, L.; COSTA, E.; SHKLOVER, V.; SPICCIA, L.; DEACON, G. B.; BIGNOZZI, C. A.; GRÄTZEL, M. 2000. Engineering of efficient panchromatic sensitizers for nanocrystalline TiO₂-based solar cells. Journal of the American Chemical Society. 123, 1613-1624.
PAVLISHCHUK, V. V.; ADDISON, A. W. 2000. Conversion constants for redox potentials measured versus different reference electrodes in acetonitrile solutions at 25° C. Inorganica Chimica Acta. 298, 97-102.
REVECO, O.; CHERRY, W. R.; MEDLEY, J.; GARBER, A; GALE, R. J.; SELBIN, J. 1986. Cyclometalated complexes of ruthenium. 3. Spectral, electrochemical and two-dimensional proton NMR of [Ru(bpy)₂(cyclometalating ligand)]+. Inorganic Chemistry. 25, 1842-1845.
SAUVAGE, J.-P.; COLLIN, J. P.; CHAMBRON, J. C.; GUILLEREZ, S.; COUDRET, C.; BALZANI, V.; BARIGELLETTI, F.; DE COLA, L.; FLAMIGNI, L. 1994. Ruthenium(II) and osmium(II) bis(terpyridine) complexes in covalently-linked multicomponent systems: synthesis, electrochemical behaviour, absorption spectra, and photochemical and photophysical properties. Chemistry Reviews. 94, 993-1019.
SCHUBERT, U.S.; ESCHBAUMER, C.; ANDRES, P.; HOFFMEIER, H.; WEIDLY, C. H.; HERDTWECK, E.; DULKEITH, E.; MORTEANI, A.; HECKER, N. E.; FELDMANN, J. 2001. 2,2′:6′,2″-Terpyridine metal complexes as building blocks for extended functional metallo-supramolecular assemblies and polymers. Synthetic Metals. 121, 1249-1252.
SORO, B.; STOCCORO, S.; MINGHETTI, G.; ZUCCZ, A.; CINELLU, M. A.; GLADIALI, S.; MANASSERO, M.; SANSONI, M. 2005. Synthesis of the first C-2 cyclopalladated derivatives of 1,3-bis(2-pyridyl)benzene. Crystal structures of [Hg(N—C—N)Cl], [Pd(N—C—N)Cl], and [Pd-2(N—C—N)(2)(mu-OAc)](2)[Hg2Cl6]. Catalytic activity in the heck reaction. Organometallics. 24, 53-61.
SULLIVAN, B. P.; CALVERT, J. M.; MEYER, T. J. 1980. Micellar effect on electron transfer. 3. Kinetics of substituted 1,10-phenanthroline complexes of iron(III) with iron(II) in the presence of sodium dodecyl sulfate Inorganic Chemistry. 19, 1404-1407.
WADMAN S. H.; LUTZ, M.; TOOKE, D. M.; SPEK, A. L.; HARTL, F.; HAVENITH, R. W. A.; VAN KLINK, G. P. M.; VAN KOTEN, G. 2009. Consequences of N,C,N′- and C,N,N′-coordination modes on electronic and photophysical properties of cyclometalated aryl ruthenium(II) complexes. Inorganic Chemistry. 48, 1887-1900.
YANG, X.-J.; DREPPER, F.; WU, B.; SUN, W.-H. I HAEHNEL, W.; JANIAK, C. 2005. From model compounds to protein binding: syntheses, characterizations and fluorescence studies of [RuII(bipy)(terpy)L]2+ complexes (bipy=2,2-bipyridine; terpy=2,2:6,2-terpyridine; L=imidazole, pyrazole and derivatives, cytochrome c). Dalton Transactions. 256-257.

1. A compound of formula (I): 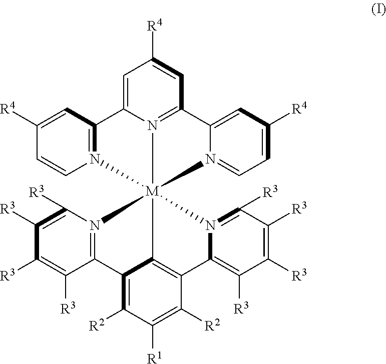
wherein M is an element belonging to Group 6, Group 8, Group 9, Group 10, or Group 11 of the long-form Periodic Table;
R¹ is an electron-donating substituent or -withdrawing substituent or H;
R² are each independently an electron-donating substituent or H;
R³ are each independently an electron-donating substituent, an electron-withdrawing substituent or H; and
R⁴ are each independently an electron-withdrawing substituents or electron-donating substituent or H.

2. A compound of the formula (II): 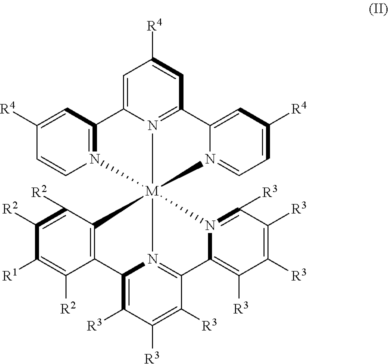
wherein M is an element belonging to Group 6, Group 8, Group 9, Group 10, or Group 11 of the long-form Periodic Table;
R¹, R², R³, R⁴ are each independently an electron-donating group, electron-withdrawing group, or H, and wherein at least one of R¹, R², R³ and R⁴ is an electron-withdrawing substituent located on a pyridine moiety.

3. The compound of claim 1 wherein M is iron, ruthenium, osmium, iridium, cobalt, palladium platinum or chromium.

4. The compound of claim 1 wherein
R¹ is an alkoxy group, an amine, an alkyl group, a substituted five-membered heterocycle, an achoring group, a fluorinated carbon, an electron-deficient aromatic or a halide;
R² are each independently an alkoxy group, an amine, an alkyl, a five-membered heterocycle or H;
R³ are each independently an alkoxy group, an amine, an alkyl, a substituted five-membered heterocycle, a halogen, an anchoring group, NO₂, an electron-deficient aromatic or H; and
R⁴ are each independently a halogen, an anchoring group, NO₂, an electron-deficient aromatic or H and at least one of R⁴ is a halogen, an anchoring group, NO₂, or an electron-deficient aromatic.

5. The compound of claim 4 wherein R⁴ are each independently CO₂H or H.

6. The compound of claim 3 wherein R² is H.

7. The compound of claim 3 wherein R¹ is a methoxy group.

8. The compound of claim 2 wherein R¹ is an electron-withdrawing substituent or H, R² are each independently an electron-withdrawing substituent or H, R³ are each independently an electron-withdrawing substituent and R⁴ are each independently an electron-donating substituent.

9. The compound of claim 2 wherein R¹ is an electron-withdrawing substituent or H, R² are each independently an electron-withdrawing substituent or H, R³ are each independently an electron-donating substituent, and R⁴ are each independently an electron-withdrawing substituent.

10. The compound of claim 2 wherein at least two of R¹, R², R³ and R⁴ are electron-withdrawing substituents located on pyridine moieties.

11. The compound of formula (III): 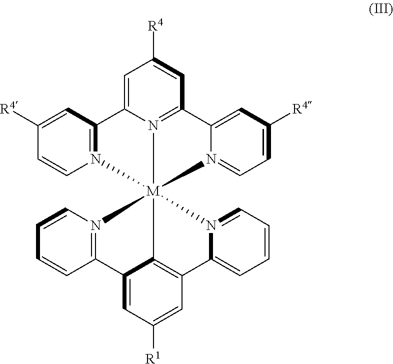
wherein M is an element belonging to Group 6, Group 8, Group 9, Group 10, or Group 11 of the long-form Periodic Table, R¹ is an alkoxy group, an amine, an alkyl or a substituted five-membered heterocycle;
R⁴ is a halogen, an anchoring group, NO₂, an electron-deficient aromatic; and
R⁴′ and R⁴″ are each independently a halogen, an anchoring group, NO₂, an electron-deficient aromatic or H.

12. The compound of claim 11 wherein R¹ is methoxy; and
R⁴ is CO₂H; and
R⁴′ and R⁴″ are each independently CO₂H or H.

13. The compound of claim 12 wherein R⁴′ and R⁴″ are H.

14. The compound of formula (IV): 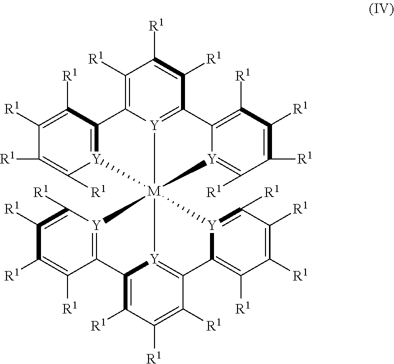
wherein M is an element belonging to Group 6, Group 8, Group 9, Group 10, or Group 11 of the long-form Periodic Table;
R¹ are each independently an electron-donating substituent or an electron-withdrawing substituent or H; and
Y=C or N, where exactly two (2) Y atoms are C and four (4) Y atoms are N.

15. A solar cell comprising an anode, a cathode and an electrolyte deposited in electrical communication with each of the anode and the cathode;
wherein the anode comprises a compound according to claim 1.

16. The solar cell of claim 15 wherein the compound is deposited on the surface of the anode.

17. The solar cell of claim 16 wherein
the anode further comprises a semiconductor layer deposited on a surface of a substrate; and
wherein the compound is deposited on a surface of the semiconductor layer.

18. The solar cell of claim 17 wherein the substrate includes electrically conductive transparent glass.

19. An anode for use in a solar cell formed by contacting a substrate with a solution comprising a compound of claim 1, thereby causing the compound to be associated with a semiconductor.

20. The anode of claim 19 wherein the substrate comprises a semiconductor deposited on a surface of the substrate.

21. The anode of claim 19 wherein the substrate comprises electrically conductive transparent glass.

22. A method for the manufacture of a solar cell comprising contacting an anode comprising a substrate with a solution comprising a compound of claim 1, thereby causing the compound to be associated with a semiconductor.

23. The method of claim 22 wherein the substrate comprises a semiconductor deposited at a surface of the substrate.

24. The method of claim 23 wherein the substrate comprises electrically conductive transparent glass.
